(19) United States
(12) Patent Application Publication
(10) Pub. No.: US 2026/0223475 A1
(43) Pub. Date: Jul. 30, 2026

(54) SOLID-STATE IMAGE CAPTURING DEVICE

(71) Applicant: SONY SEMICONDUCTOR SOLUTIONS CORPORATION, KANAGAWA (JP)

(72) Inventors: NAOYUKI OSAWA, KANAGAWA (JP); YOSHIMICHI KUMAGAI, KANAGAWA (JP); MASASHI BANDO, KANAGAWA (JP); TORU SHIRAKATA, KANAGAWA (JP); SHUNYA AKIYAMA, KANAGAWA (JP); TAKASHI ABE, KANAGAWA (JP)

(21) Appl. No.: 19/141,694

(22) PCT Filed: Nov. 24, 2023
(86) PCT No.: PCT/JP2023/042102

§ 371 Date: Jun. 20, 2025

(30) Foreign Application Priority Data
Dec. 28, 2022 (JP) 2022-212420

(51) Int. Cl. H10F 39/00

(52) U.S. Cl. CPC H10F 39/811; H10F 39/8037; H10F 39/809

(57) ABSTRACT

To provide a solid-state image capturing device in which pixel transistors can appropriately be laid out.

A solid-state image capturing device according to the present disclosure includes a first substrate, a floating diffuser disposed in the first substrate, a first transistor disposed on the first substrate, a first insulating film disposed on the first substrate and the first transistor, a first interconnect disposed in the first insulating film and electrically connected to the floating diffuser and the first transistor, a second substrate disposed on the first insulating film, a second transistor disposed on the second substrate, and a second insulating film disposed on the second substrate and the second transistor.

### TECHNICAL FIELD

The present disclosure relates to a solid-state image capturing device.

### BACKGROUND ART

Some solid-state image capturing devices are fabricated by affixing a first substrate on which photoelectric transducers and floating diffusers are provided and a second substrate to each other. The solid-state image capturing devices thus fabricated are likely to impose constraints on a layout of pixel transistors at respective pixels.

For example, when a pixel transistor is placed on the first substrate, a parasitic capacitance tends to occur between interconnects belonging to the pixel transistor and the second substrate. Furthermore, when a through plug is placed in the second substrate, it may possibly make it difficult to place pixel transistors on the second substrate and may possibly lead to an increase in the parasitic capacitance acting on the interconnects. As a result, a degree of freedom with which to lay out the first and second substrates is liable to decrease.

### CITATION LIST

### Patent Literature

### [PTL 1]

PCT Patent Publication No. WO2019/130702

### [PTL 2]

Japanese Patent Laid-open No. 2019-84191A

### SUMMARY

### Technical Problem

The present disclosure provides a solid-state image capturing device in which pixel transistors can appropriately be laid out.

### Solution to Problem

A solid-state image capturing device according to an aspect of the present disclosure includes a first substrate, a floating diffuser disposed in the first substrate, a first transistor disposed on the first substrate, a first insulating film disposed on the first substrate and the first transistor, a first interconnect disposed in the first insulating film and electrically connected to the floating diffuser and the first transistor, a second substrate disposed on the first insulating film, a second transistor disposed on the second substrate, and a second insulating film disposed on the second substrate and the second transistor. With this arrangement, by placing the first transistor on the first substrate rather than the second substrate, for example, it is possible to appropriately lay out the first transistor.

Moreover, according to the first aspect, the first transistor may be an amplifying transistor for converting electric charges stored in the floating diffuser to a voltage signal. With this arrangement, for example, it is possible to appropriately lay out the first transistor that is the amplifying transistor.

Moreover, the solid-state image capturing device according to the first aspect may further include a third transistor disposed on the first substrate, a second interconnect disposed in the first insulating film and electrically connected to the third transistor, a third insulating film disposed between the first insulating film and the second insulating film in the second substrate and extending through the second substrate, and one or more first plugs disposed in the third insulating film, in which the one or more first plugs may include a first plug disposed on the second interconnect and may not be disposed on the first interconnect. With this arrangement, for example, it is possible to reduce a parasitic capacitance acting on the first interconnect even though the first plug (through plug) is present.

Moreover, according to the first aspect, the third transistor may be a transfer transistor for transferring electric charges generated by a photoelectric transducer disposed in the first substrate. With this arrangement, for example, it is possible to lay out the first plug (through plug) on an interconnect for the transfer transistor.

Moreover, the solid-state image capturing device according to the first aspect may further include a fourth transistor disposed on the first substrate and a third interconnect disposed in the first insulating film and electrically connected to the fourth transistor, in which the one or more first plugs may not be disposed on the third interconnect. With this arrangement, for example, it is possible to reduce a parasitic capacitance acting on the third interconnect even though the first plug (through plug) is present.

Moreover, according to the first aspect, the fourth transistor may be a resetting transistor for resetting a potential of the floating diffuser. With this arrangement, for example, it is possible to appropriately lay out the fourth transistor that is the resetting transistor.

Moreover, according to the first aspect, at least a portion of the first insulating film may be an insulating film having a dielectric constant lower than the dielectric constant of silicon oxide. With this arrangement, for example, it is possible to reduce a parasitic capacitance acting on the first interconnect with the lower dielectric constant.

Moreover, the solid-state image capturing device according to the first aspect may further include a fourth insulating film disposed between the first insulating film and the second insulating film in the second substrate and extending through the second substrate, in which the first interconnect may be disposed in a position superposed on the fourth insulating film as viewed in plan. With this arrangement, for example, it is possible to restrain a parasitic capacitance between the first interconnect and the second substrate.

Moreover, according to the first aspect, at least a portion of the fourth insulating film may be an insulating film having a dielectric constant lower than the dielectric constant of silicon oxide. With this arrangement, for example, it is possible to reduce a parasitic capacitance acting on the first interconnect with the lower dielectric constant.

Moreover, according to the first aspect, the first interconnect may be disposed in a position superposed on a hollow region extending through the second substrate as viewed in plan. With this arrangement, for example, it is possible to reduce a parasitic capacitance acting on the first interconnect with the lower dielectric constant.

Moreover, according to the first aspect, the first interconnect may be held in contact with the hollow region. With this arrangement, for example, it is possible to increase the volume of the hollow region.

Moreover, the solid-state image capturing device according to first aspect may further include a fourth insulating film disposed between the first insulating film and the second insulating film in the second substrate and extending through the second substrate, in which the third interconnect may be disposed in a position superposed on the fourth insulating film as viewed in plan. With this arrangement, for example, it is possible to reduce a parasitic capacitance acting on the third interconnect with the lower dielectric constant.

Moreover, the solid-state image capturing device according to the first aspect may further include a fifth insulating film disposed between the first insulating film and the second insulating film in the second substrate and extending through the second substrate, in which the first substrate may include a first portion annularly surrounded by the fifth insulating film. With this arrangement, for example, it is possible to separate a first portion of the second substrate from another portion of the second substrate.

Moreover, according to the first aspect, the first interconnect may be disposed in a position superposed on the first portion as viewed in plan. With this arrangement, for example, it is possible to restrain a parasitic capacitance between the first interconnect and the second substrate.

Moreover, the solid-state image capturing device according to the first aspect may further include a second plug disposed on the first portion for controlling a potential of the first portion. With this arrangement, for example, it is possible to restrain a parasitic capacitance between the first interconnect and the second substrate by controlling the potential of the first portion.

Moreover, the solid-state image capturing device according to the first aspect may further include a resetting transistor for resetting a potential of the floating diffuser and a conversion-efficiency switching transistor disposed between the floating diffuser and the resetting transistor for switching between conversion efficiencies of a photoelectric transducer disposed in the first substrate. With this arrangement, for example, it is possible to electrically connect the resetting transistor to the floating diffuser through the conversion-efficiency switching transistor.

Moreover, according to the first aspect, the resetting transistor may be disposed on the first substrate. With this arrangement, for example, it is possible to electrically connect the resetting transistor to the conversion-efficiency switching transistor not through the first plug.

Moreover, according to the first aspect, the resetting transistor may be disposed on the second substrate. With this arrangement, for example, it is possible to electrically connect the resetting transistor to the conversion-efficiency switching transistor through the first plug.

Moreover, the solid-state image capturing device according to the first aspect may further include a circuit disposed on the second substrate and including a transistor and a capacitor. With this arrangement, for example, it is possible to enhance the functions of the solid-state image capturing device.

Moreover, according to the first aspect, the circuit may be a sample and hold circuit. With this arrangement, for example, it is possible to add a global shutter function to the solid-state image capturing device.

### BRIEF DESCRIPTION OF DRAWINGS

FIG. 1 is a block diagram illustrating a configuration of a solid-state image capturing device according to a first embodiment.

FIG. 2 is a cross-sectional view illustrating a structure of the solid-state image capturing device according to the first embodiment.

FIG. 3 is a circuit diagram illustrating the configuration of the solid-state image capturing device according to the first embodiment.

FIG. 4 depicts plan views illustrating the structures of the solid-state image capturing device according to the first embodiment.

FIG. 5 is a cross-sectional view illustrating a structure of a solid-state image capturing device according to a first modification of the first embodiment.

FIG. 6 depicts plan views illustrating the structures of the solid-state image capturing device according to the first modification of the first embodiment.

FIG. 7 is a cross-sectional view illustrating a structure of a solid-state image capturing device according to a second modification of the first embodiment.

FIG. 8 is a cross-sectional view illustrating a structure of a solid-state image capturing device according to a third modification of the first embodiment.

FIG. 9 is a cross-sectional view illustrating a structure of a solid-state image capturing device according to a second embodiment.

FIG. 10 depicts plan views illustrating the structures of the solid-state image capturing device according to the second embodiment.

FIG. 11 is a cross-sectional view illustrating a structure of a solid-state image capturing device according to a third embodiment.

FIG. 12 depicts plan views illustrating the structures of the solid-state image capturing device according to the third embodiment.

FIG. 13 depicts circuit diagrams illustrating the configurations of a solid-state image capturing device according to a fourth embodiment.

FIG. 14 is a circuit diagram illustrating the configuration of a solid-state image capturing device according to a fifth embodiment.

FIG. 15 is a circuit diagram illustrating the configuration of a solid-state image capturing device according to a sixth embodiment.

FIG. 16 is a circuit diagram illustrating the configuration of a solid-state image capturing device according to a seventh embodiment.

FIG. 17 is a circuit diagram illustrating the configuration of a solid-state image capturing device according to an eighth embodiment.

FIG. 18 is a circuit diagram illustrating the configuration of a solid-state image capturing device according to a ninth embodiment.

FIG. 19 is a circuit diagram illustrating the configuration of a solid-state image capturing device according to a tenth embodiment.

FIG. 20 is a cross-sectional view illustrating a structure of a solid-state image capturing device according to an eleventh embodiment.

FIG. 21 is a block diagram illustrating a configurational example of an electronic device.

FIG. 22 is a block diagram illustrating a configurational example of a mobile body control system.

FIG. 23 is a plan view illustrating a specific example of set positions of an image capturing section illustrated in FIG. 22.

FIG. 24 is a view illustrating a general configurational example of an endoscopic surgical system.

FIG. 25 is a block diagram illustrating an example of functional configurations of a camera head and a CCU.

### DESCRIPTION OF EMBODIMENTS

Embodiments of the present disclosure will be described hereinbelow with reference to the drawings.

### First Embodiment

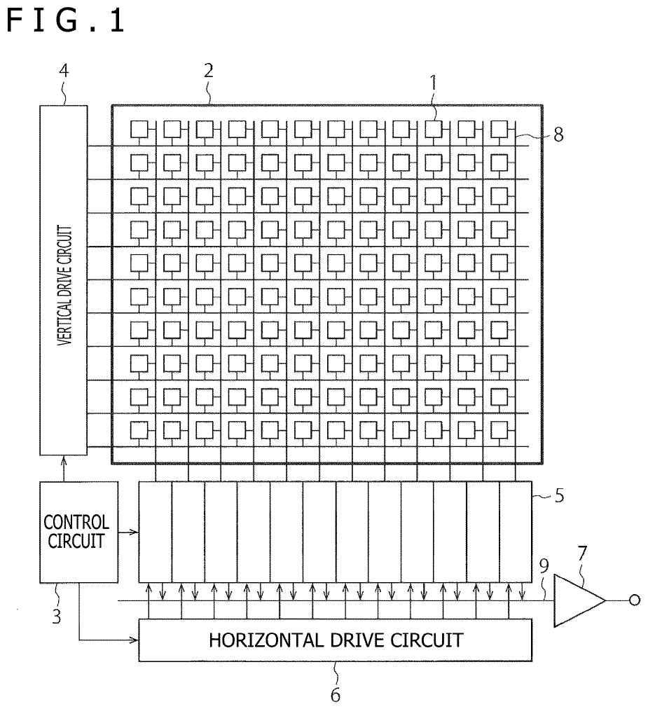

FIG. 1 is a block diagram illustrating a configuration of a solid-state image capturing device according to a first embodiment.

The solid-state image capturing device illustrated in FIG. 1 includes an image sensor (CIS) of a CMOS (Complementary Metal Oxide Semiconductor) type and includes a pixel array area 2 having a plurality of pixels 1, a control circuit 3, a vertical drive circuit 4, a plurality of column signal processing circuits 5, a horizontal drive circuit 6, an output circuit 7, a plurality of vertical signal lines (VSL) 8, and a horizontal signal line (HSL) 9.

Each of the pixels 1 includes a photodiode functioning as a photoelectric transducer and MOS transistors functioning as pixel transistors. Examples of the pixel transistors include transfer transistors, resetting transistors, amplifying transistors, selecting transistors, and switching transistors, for example. These pixel transistors may be shared by some pixels 1.

In the pixel array area 2, the multiple pixels 1 are arranged in a two-dimensional array. The pixel array area 2 includes an effective pixel area for detecting light, performing photoelectric conversion thereon, and outputting signal charges generated by the photoelectric conversion and a black reference pixel area for outputting optical black as a black level reference. Generally, the black reference pixel area is disposed in an outer peripheral portion of the effective pixel area.

The control circuit 3 generates various signals that provide references for operation of the vertical drive circuit 4, the column signal processing circuits 5, and the horizontal drive circuit 6, on the basis of a vertical synchronizing signal, a horizontal synchronizing signal, a master clock, and the like. The signals generated by the control circuit 3 include a clock signal and control signals, for example, that are input to the vertical drive circuit 4, the column signal processing circuits 5, and the horizontal drive circuit 6.

The vertical drive circuit 4 includes shift registers, for example, and vertically scans rows of the pixels 1 in the pixel array area 2. The vertical drive circuit 4 also supplies pixel signals based on signal charges generated by the pixels 1 through the vertical signal lines 8 to the column signal processing circuit 5.

The column signal processing circuits 5 are disposed in alignment with the respective columns of the pixels in the pixel array area 2, for example, and perform signal processing on the signals output from the rows of the pixels 1 per column on the basis of signals from the black reference pixel area. Examples of the signal processing are noise removal and signal amplification.

The horizontal drive circuit 6 includes shift registers, for example, and supplies pixel signals from the respective column signal processing circuits 5 to the horizontal signal line 9.

The output circuit 7 performs signal processing on the signals supplied from the respective column signal processing circuits 5 through the horizontal signal line 9 and outputs the processed signals.

Note that the pixel array area 2 according to the present embodiment may include only one of pixels 1 for detecting visible light and pixels 1 for detecting light other than visible light, or may include both pixels 1 for detecting visible light and pixels 1 for detecting light other than visible light. The light other than visible light may be infrared light, for example.

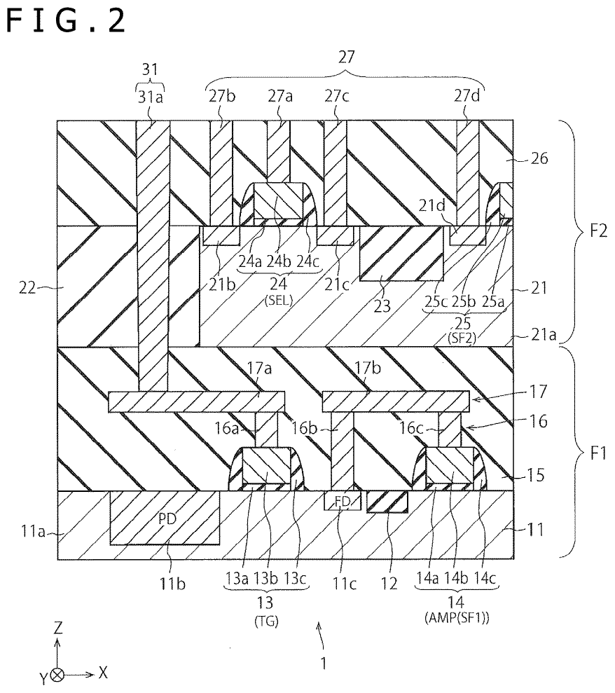

FIG. 2 is a cross-sectional view illustrating the structure of the solid-state image capturing device according to the first embodiment. FIG. 2 illustrates one of the pixels 1 in the solid-state image capturing device according to the present embodiment.

FIG. 2 depicts an X-axis, a Y-axis, and a Z-axis that are perpendicular to each other. An X direction and a Y direction correspond to lateral directions (horizontal directions), and a Z direction corresponds to an upright direction (vertical direction). Moreover, a +Z direction corresponds to an upward direction, and a −Z direction corresponds to a downward direction. In addition, the −Z direction may or may not be in strict alignment with the gravitational direction.

The solid-stage image capturing device according to the present embodiment illustrated in FIG. 2 includes a substrate 11, an element-separating insulating film 12, a pixel transistor 13, a pixel transistor 14, an interlayer insulating film 15, a plurality of contact plugs 16, an interconnect layer 17, a substrate 21, an insulating film 22, an element-separating insulating film 23, a pixel transistor 24, a pixel transistor 25, an interlayer insulating film 26, a plurality of contact plugs 27, and a through plug 31. The substrate 11, the pixel transistor 13, the pixel transistor 14, and the interlayer insulating film 15 represent examples of a first substrate, a third transistor, a first transistor, and a first insulating film, respectively, according to the present disclosure. The substrate 21, the insulating film 22, the pixel transistors 24 and 25, and the interlayer insulating film 26 represent examples of a second substrate, a third insulating film, a second transistor, and a second insulating film, respectively, according to the present disclosure. The through plug 31 represents an example of a first plug according to the present disclosure.

The substrate 11 includes a semiconductor substrate such as an Si (silicon) substrate, for example. In FIG. 2, the X direction and the Y direction extend parallel to the upper surface of the substrate 11 and the Z direction extends perpendicularly to the upper surface of the substrate 11. In FIG. 2, the upper surface of the substrate 11 represents a face side of the substrate 11 and the lower surface of the substrate 11 represents a reverse side of the substrate 11. The substrate 11 includes a well region 11a, a diffusion region 11b, and a diffusion region 11c. FIG. 2 further illustrates a photodiode PD and a floating diffuser FD formed in the substrate 11. The photodiode PD is formed by a PN junction between the well region 11a and the diffusion region 11b. The floating diffuser FD is formed by the diffusion region 11c. The well region 11a includes a P-type semiconductor region, for example. The diffusion regions 11b and 11c include N-type semiconductor regions, for example. The diffusion regions 11b and 11c are also referred to as active regions.

The element-separating insulating film 12 is formed in the substrate 11. The element-separating insulating film 12 includes an SiO₂ (silicon oxide) film, for example. In FIG. 2, the element-separating insulating film 12 is disposed between the pixel transistor 13 and the pixel transistor 14.

The pixel transistor 13 includes a gate insulating film 13a and a gate electrode 13b that are successively formed on the substrate 11 and side-wall insulating films 13c formed on both sides of the gate electrode 13b. The gate insulating film 13a includes an SiO₂ film, for example. The gate electrode 13b includes an N-type semiconductor layer (e.g., a polysilicon layer), for example. As illustrated in FIG. 2, the gate electrode 13b is disposed in the vicinity of the diffusion regions 11b and 11c. The side-wall insulating films 13c include SiO₂ films and/or SiN (silicon nitride) films, for example. The pixel transistor 13 includes a transfer transistor TG, for example.

The pixel transistor 14 includes a gate insulating film 14a and a gate electrode 14b that are successively formed on the substrate 11 and side-wall insulating films 14c formed on both sides of the gate electrode 14b. The gate insulating film 14a includes an SiO₂ film, for example. The gate electrode 14b includes an N-type semiconductor layer (e.g., a polysilicon layer), for example. As illustrated in FIG. 2, the gate electrode 14b is electrically connected to the diffusion region 11c (the floating diffuser FD). The side-wall insulating films 14c include SiO₂ films and/or SiN films, for example. The pixel transistor 14 includes an amplifying transistor AMP (SF1), for example.

The interlayer insulating film 15 is formed on the substrate 11, the element-separating insulating film 12, and the pixel transistors 13 and 14 in covering relation to the pixel transistors 13 and 14. The interlayer insulating film 15 includes a layered insulating film including an SiO₂ film and other films, for example.

The contact plug 16 is formed in the interlayer insulating film 15 and disposed on the gate electrode 13b or the gate electrode 14b. FIG. 2 illustrates a plug 16a, a plug 16b, and a plug 16c as an example of the contact plug 16. The plug 16a is disposed on the gate electrode 13b. The plug 16b is disposed on the diffusion region 11c. The plug 16c is disposed on the gate electrode 14b. The plugs 16a through 16c include an N-type semiconductor layer (e.g., a polysilicon layer), for example.

The interconnect layer 17 is formed in the interlayer insulating film 15 and disposed on the contact plug 16. In FIG. 2, the interconnect layer 17 includes interconnects 17a and 17b that are separate from each other. The interconnect 17a is disposed on the plug 16a. The interconnect 17b is disposed on the plugs 16b and 16c, electrically interconnecting the plugs 16b and 16c. As a result, the pixel transistor 14 (the gate electrode 14b) and the diffusion region 11c (the floating diffuser FD) are electrically connected to each other by the interconnect 17b. The interconnects 17a and 17b include an N-type semiconductor layer (e.g., a polysilicon layer), for example. The interconnects 17a and 17b are also referred to as local interconnects. Furthermore, the interconnect 17b is also referred to an FD interconnect. The interconnect 17b and the interconnect 17a represent an example of a first interconnect and a second interconnect, respectively, according to the present disclosure.

The substrate 21 is disposed on the interlayer insulating film 15. The solid-state image capturing device according to the present embodiment includes the substrates 11 and 21 that are affixed to each other. The substrate 21 is affixed to the substrate 11 through the interlayer insulating film 15. The substrate 21 includes a semiconductor substrate such as an Si substrate, for example. In FIG. 2, the X direction and the Y direction extend parallel to the upper surface of the substrate 21, and the Z direction extends perpendicularly to the upper surface of the substrate 21. In FIG. 2, the upper surface of the substrate 21 represents a face side of the substrate 21 and the lower surface of the substrate 21 represents a reverse side of the substrate 21. The substrate 21 includes a well region 21a, a diffusion region 21b, a diffusion region 21c, and a diffusion region 21d. The well region 21a includes a P-type semiconductor region, for example. The diffusion regions 21b through 21d include N-type semiconductor regions, for example. The diffusion regions 21b through 21d are also referred to as active regions.

The insulating film 22 is embedded in an opening defined in the substrate 21. The opening extends through the substrate 21. Therefore, the insulating film 22 extends through the substrate 21 and is disposed on the interlayer insulating film 15. The insulating film 22 includes an SiO₂ film, for example.

The element-separating insulating film 23 is formed in the substrate 21. The element-separating insulating film 23 includes an SiO₂ film, for example. In FIG. 2, the element-separating insulating film 23 is disposed between the pixel transistor 24 and the pixel transistor 25. In FIG. 2, moreover, the element-separating insulating film 23 is disposed in a position superposed on the interconnect 17b as viewed in plan, i.e., in a position superposed on the interconnect 17b as viewed in the Z direction.

The pixel transistor 24 includes a gate insulating film 24a and a gate electrode 24b that are successively formed on the substrate 21 and side-wall insulating films 24c formed on both sides of the gate electrode 24b. The gate insulating film 24a includes an SiO₂ film, for example. The gate electrode 24b includes an N-type semiconductor layer (e.g., a polysilicon layer), for example. The side-wall insulating films 24c include SiO₂ films and/or SiN films, for example. The pixel transistor 24 includes a selection transistor SEL, for example. Note that the diffusion region 21b functions as one of the source and drain regions of the pixel transistor 24 and the diffusion region 21c functions as the other of the source and drain regions of the pixel transistor 24.

The pixel transistor 25 includes a gate insulating film 25a and a gate electrode 25b that are successively formed on the substrate 21 and side-wall insulating films 25c formed on both sides of the gate electrode 25b (one of the side-wall insulating films 25c is omitted from illustration). The gate insulating film 25a includes an SiO₂ film, for example. The gate electrode 25b includes an N-type semiconductor layer (e.g., a polysilicon layer), for example. The side-wall insulating films 25c include SiO₂ films and/or SiN films, for example. The pixel transistor 25 includes an amplifying transistor (rear-stage amplifying transistor) SF2 that is different from the amplifying transistor AMP (SF1), for example. Note that the diffusion region 21d functions as one of the source and drain regions of the pixel transistor 25 and another diffusion region in the substrate 21 functions as the other of the source and drain regions of the pixel transistor 25.

The interlayer insulating film 26 is formed on the substrate 21, the insulating film 22, the element-separating insulating film 23, and the pixel transistors 24 and 25 in covering relation to the pixel transistors 24 and 25. The interlayer insulating film 26 includes a layered insulating film including an SiO₂ film and other films, for example.

The contact plug 27 is formed in the interlayer insulating film 26 and disposed on the substrate 21, the gate electrode 24b, or the gate electrode 25b. FIG. 2 illustrates a plug 27a, a plug 27b, a plug 27c, and a plug 27d as an example of the contact plug 27. The plug 27a is disposed on the gate electrode 24b. The plug 27b is disposed on the diffusion region 21b. The plug 27c is disposed on the diffusion region 21c. The plug 27d is disposed on the diffusion region 21d. The plugs 27a through 27d include an N-type semiconductor layer (e.g., a polysilicon layer), for example. The solid-state image capturing device according to the present embodiment further includes a plug (not depicted) disposed on the gate electrode 25b as an example of the contact plug 27.

The through plug 31 is formed in the interlayer insulating film 15, the insulating film 22, and the interlayer insulating film 26 and extends through the substrate 21. The insulating film 22 is interposed between the substrate 21 and the through plug 31 and electrically isolates the substrate 21 and the through plug 31 from each other. The through plug 31 is of a columnar shape extending in the Z direction, for example, and has a lower end positioned in the interlayer insulating film 15 and an upper end positioned in the interlayer insulating film 26. The through plug 31 includes a metal layer, for example. The through plug 31 includes an Al (aluminum) layer, a W (tungsten) layer, or a Cu (copper) layer, for example. The through plug 31 may further include a barrier metal layer. The through plug 31 is also referred to as TCS.

Each of the pixels 1 according to the present embodiment includes a plurality of through plugs 31 as described later. FIG. 2 illustrates a plug 31a as an example of the through plugs 31. The plug 31a is disposed on the interconnect 17a and is electrically connected to the interconnect 17a. Therefore, the plug 31a is electrically connected to the pixel transistor 13 (the gate electrode 13b) through the interconnect 16b and the plug 16a. Note that each of the through plugs 31 is disposed beneath an interconnect, not depicted, provided in the interlayer insulating film 26 and is electrically connected to the interconnect, for example.

The solid-state image capturing device according to the present embodiment is of a double-layer structure including the substrate 11 (a first layer) and the substrate 21 (a second layer). Regions in the substrate 11 and the interlayer insulating film 15 are called a “first floor” and regions in the substrate 21 and the interlayer insulating film 26 are called a “second floor.” For example, the photodiode PD, the floating diffuser FD, and the pixel transistors 13 and 14 are disposed in the first floor and the pixel transistors 24 and 25 are disposed in the second floor. Furthermore, the through plugs 31 extend across and over the first floor and the second floor. In FIG. 2, the first floor is denoted by F1 and the second floor is denoted by F2.

Note that each of the pixel transistors 13, 14, 24, and 25 may include a transistor other than the transfer transistor TG, the amplifying transistor AMP (SF1), the selection transistor SEL, and the rear-stage amplifying transistor SF2. For example, either of the pixel transistors 13, 14, 24, and 25 may include a resetting transistor or a switching transistor.

As described above, the solid-state image capturing device according to the present embodiment has the plug 31a (the through plug 31) extending through the substrate 21. The plug 31a disposed in the substrate 21 tends to make its presence obstructive, resulting in difficulty placing the pixel transistor 23 on the substrate 21. According to the present embodiment, however, the plug 31a that is disposed on the interconnect 16a can be placed in the substrate 21, so that the pixel transistors 24 and 25 can easily be disposed on the substrate 21. The reason is that the interconnect 16a may be disposed in an appropriate position to allow the plug 31a to be disposed in a position where it will not obstruct the pixel transistors 24 and 25 to be disposed on the substrate 21.

Furthermore, the solid-state image capturing device according to the present embodiment has in the first floor the pixel transistor 14 (the amplifying transistor AMP) that is electrically connected to the floating diffuser FD. If the pixel transistor 14 is disposed in the second floor, then the interconnect and the plug that electrically connect the floating diffuser FD and the pixel transistor 14 will have their entire lengths increased, thus increasing the parasitic capacitance caused by the interconnect and the plug. According to the present embodiment, since the pixel transistor 14 is disposed in the first floor, the interconnect 17b and the plugs 16c and 16c that electrically connect the floating diffuser FD and the pixel transistor 14 have their entire lengths reduced, thereby making it possible to reduce the parasitic capacitance referred to above. According to the present embodiment, moreover, as the entire lengths of the interconnect 17b and the plugs 16c and 16c are reduced, it is possible to restrain process variations of the entire lengths of the interconnect 17b and the plugs 16c and 16c, and to restrain variations of the parasitic capacitance. It is thus possible to restrain variations of the conversion efficiency between the pixels 1.

The interconnect 17b according to the present embodiment electrically connects the floating diffuser FD in the first floor and the pixel transistor 14 in the first floor. Consequently, the through plug 31 according to the present embodiment is not disposed on the interconnect 17b. This makes it possible to prevent the parasitic capacitance caused by the through plug 31 from acting on the interconnect 17b. In addition, the through plug 31 according to the present embodiment includes the plug 31a disposed on the interconnect 17a. The plug 31a makes it possible to electrically connect the pixel transistor 13 to a circuit in the second floor.

Note that the interconnect layer 17 that includes the interconnects 17a and 17b should preferably include a highly thermally resistant material because a thermal load is imposed on the interconnect layer 17 in a process after it has been formed. Examples of the highly thermally resistant material are polysilicon, tungsten (W), and copper (Cu).

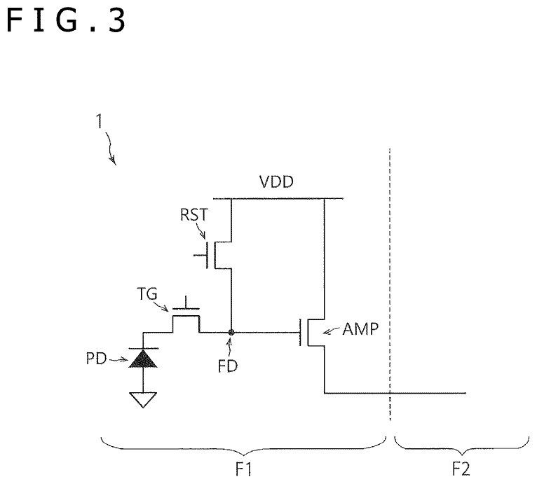

FIG. 3 is a circuit diagram illustrating the configuration of the solid-state image capturing device according to the first embodiment.

As illustrated in FIG. 3, each of the pixels 1 includes in the first floor (F1) the photodiode PD, the floating diffuser FD, the transfer transistor TG, the resetting transistor RST, and the amplifying transistor AMP. At least some of these transistors may be shared by a plurality of pixels 1.

The photodiode PD performs photoelectric conversion on incident light. The photodiode PD has an anode electrically connected to ground and a cathode electrically connected to the transfer transistor TG. Applying light to the photodiode PD is referred to as exposure of the photodiode PD.

The transfer transistor TG transfers electric charges generated by the photoelectric conversion to the floating diffuser FD. One of the source and drain of the transfer transistor TG is electrically connected to the photodiode PD, and the other of the source and drain of the transfer transistor TG is electrically connected to the floating diffuser FD.

The floating diffuser FD stores the electric charges transferred by the transfer transistor TG. The floating diffuser FD is electrically connected to the transfer transistor TG, the resetting transistor RST, and the amplifying transistor AMP.

Before exposure of the photodiode PD is started, the resetting transistor RST discharges the electric charges from the floating diffuser FD to reset the potential of the floating diffuser FD to a power source voltage (VDD). One of the source and drain of the resetting transistor RST is electrically connected to the power source voltage and the other of the source and drain of the resetting transistor RST is electrically connected to the floating diffuser FD.

The amplifying transistor AMP receives the electric charges transferred to the floating diffuser FD at its gate and outputs the electric charges to a switching transistor SW (not depicted in FIG. 3) via a source follower. The gate of the amplifying transistor AMP is electrically connected to the floating diffuser FD. One of the source and drain of the amplifying transistor AMP is electrically connected to the power source voltage and the other of the source and drain of the amplifying transistor AMP is electrically connected to the switching transistor SW. The amplifying transistor AMP converts the electric charges stored in the floating diffuser FD to a voltage signal and outputs the voltage signal to the switching transistor SW.

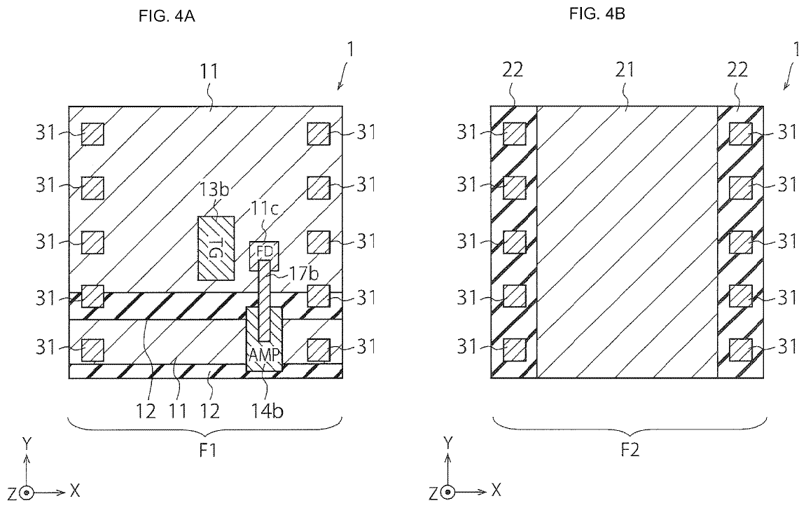

FIG. 4 depicts plan views illustrating the structures of the solid-state image capturing device according to the first embodiment. A and B in FIG. 4 illustrate, in a simplified fashion, the structure in the first floor and the structure in the second floor of a pixel 1 in the solid-state image capturing device according to the present embodiment.

A in FIG. 4 illustrates the substrate 11, the diffusion region 11b (the floating diffuser FD), the element-separating insulating film 12, the gate electrode 13b in the pixel transistor 13 (the transfer transistor TG), the gate electrode 14b in the pixel transistor 14 (the amplifying transistor AMP), the interconnect 17b (FD interconnect) in the interconnect layer 17, and the like. B in FIG. 4 illustrates the substrate 21, the insulating film 22, and the like. Note that the pixel transistors 13 and 14 are not positioned on the same XZ plane in A in FIG. 4, but are depicted in the same cross section for illustrative purposes. This holds true for other components in the solid-state image capturing device according to the present embodiment.

A and B in FIG. 4 also illustrate a plurality of through plugs 31 extending through the substrate 21. The ten through plugs 31 illustrated in A in FIG. 4 and the ten through plugs 31 illustrated in B in FIG. 4 are identical to each other. One of these through plugs 31 is the plug 31a.

### (1) First Modification

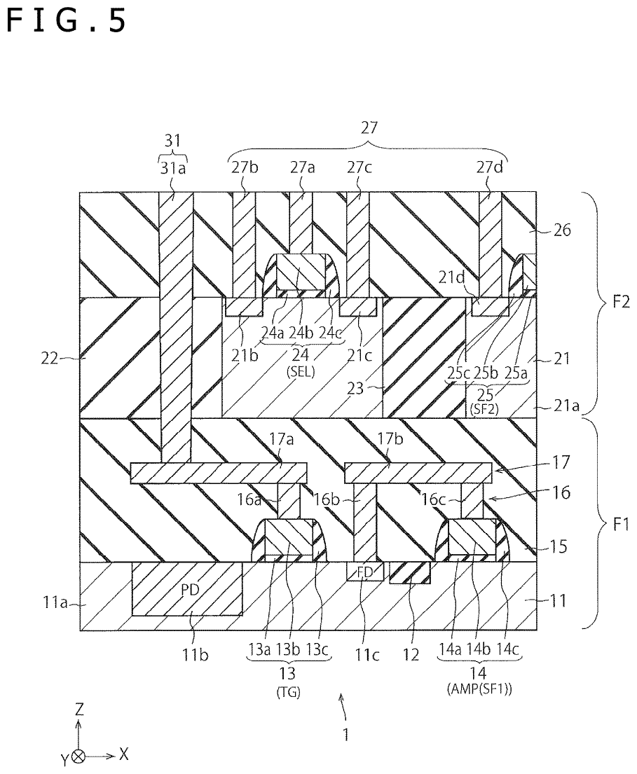

FIG. 5 is a cross-sectional view illustrating a structure of a solid-state image capturing device according to a first modification of the first embodiment.

The solid-state image capturing device (FIG. 5) according to the present modification includes similar components to those of the solid-state image capturing device (FIG. 2) according to the first embodiment. However, the element-separating insulating film 23 according to the present modification extends through the substrate 21 and is disposed on the interlayer insulating film 15, as with the insulating film 22. According to the present modification, the insulating film 22 and the element-separating insulating film 23 are provided between the interlayer insulating film 15 and the interlayer insulating film 26 and held in contact with the lower surface of the interlayer insulating film 15 and the upper surface of the interlayer insulating film 26. The element-separating insulating film 23 according to the present modification represents an example of a fourth insulating film according to the present disclosure.

The interconnect 17b according to the present modification, as with the interconnect 17b according to the first embodiment, is disposed in a position superposed on the element-separating insulating film 23 as viewed in plan. According to the first embodiment, since the element-separating insulating film 23 does not extend through the substrate 21, a parasitic capacitance occurs between the interconnect 17b and the substrate 21. According to the present modification, on the other hand, as the element-separating insulating film 23 extends through the substrate 21, it is possible to restrain a parasitic capacitance between the interconnect 17b and the substrate 21. According to the present modification, stated otherwise, it is possible to restrain a parasitic capacitance acting on the interconnect 17b.

Incidentally, according to the present modification, a portion of the interconnect 17b is superposed on the element-separating insulating film 23 as viewed in plan. According to the present modification, however, the interconnect 17b in its entirety may be superposed on the element-separating insulating film 23 as viewed in plan. The latter arrangement makes it possible to further restrain a parasitic capacitance acting on the interconnect 17b.

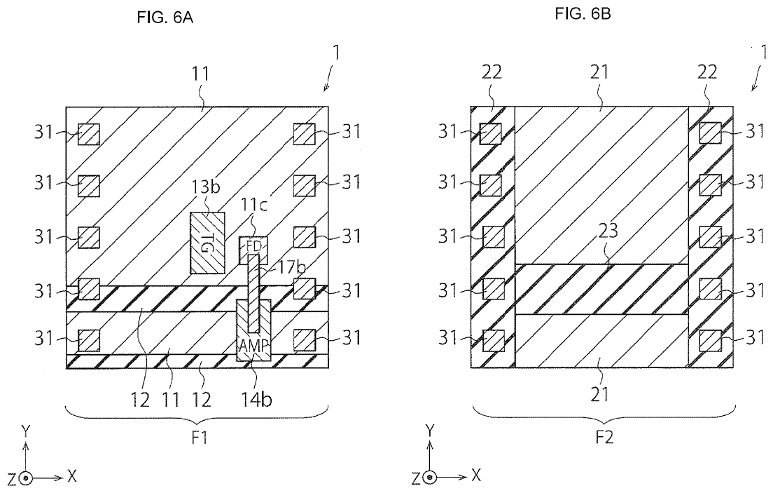

FIG. 6 depicts plan views illustrating the structures of the solid-state image capturing device according to the first modification of the first embodiment. A and B in FIG. 6 illustrate, in a simplified fashion, the structure in the first floor and the structure in the second floor of a pixel 1 in the solid-state image capturing device according to the present modification.

A and B in FIG. 6 correspond respectively to A and B in FIG. 4. However, B in FIG. 6 illustrates the element-separating insulating film 23 that is not illustrated in A in FIG. 4 for the sake of convenience. As illustrated in A and B in FIG. 6, the interconnect 17b according to the present modification is disposed in a position superposed on the element-separating insulating film 23 as viewed in plan.

### (2) Second Modification

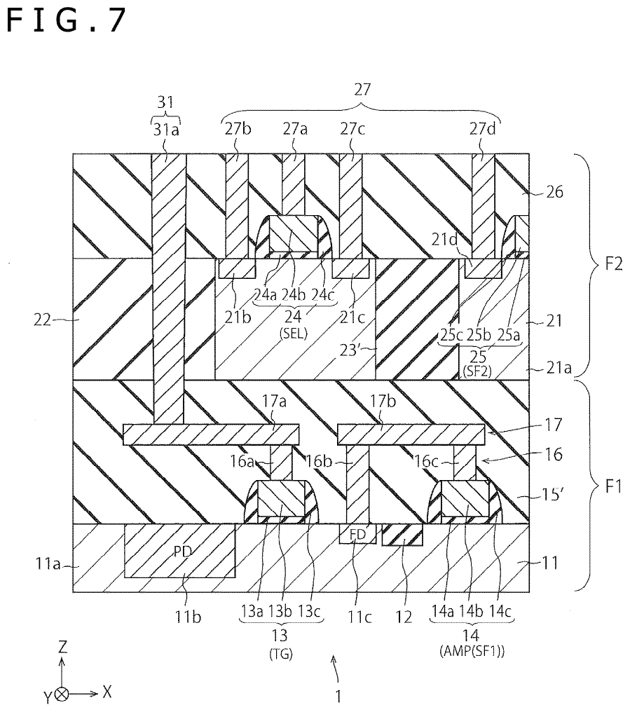

FIG. 7 is a cross-sectional view illustrating a structure of a solid-state image capturing device according to a second modification of the first embodiment.

The solid-state image capturing device (FIG. 7) according to the present modification includes similar components to those of the solid-state image capturing device (FIG. 5) according to the first modification. However, the solid-state image capturing device according to the present modification includes an interlayer insulating film 15′ instead of the interlayer insulating film 15 and an element-separating insulating film 23′ instead of the element-separating insulating film 23.

The interlayer insulating film 15′ includes an insulating film having a dielectric constant lower than the dielectric constant of SiO₂, for example. Similarly, the interlayer insulating film 23′ includes an insulating film having a dielectric constant lower than the dielectric constant of SiO₂, for example. An example of these insulating films is an SiOC (silicon oxycarbide). Note that SiO₂ has a relative dielectric constant of approximately 4.1 and SiOC has a relative dielectric constant of approximately 2.9. According to the present modification, the dielectric constant of the insulating film in the vicinity of the interconnect 17b is reduced to make it possible to further restrain the parasitic capacitance acting on the interconnect 17b.

Incidentally, according to the present modification, rather than using an SiOC film as the interlayer insulating film 15′ in its entirety, an SiOC film may be used as part of the interlayer insulating film 15′. Similarly, according to the present modification, rather than using an SiOC film as the element-separating insulating film 23′ in its entirety, an SiOC film may be used as part of the element separating insulating film 23′. For example, a portion of the interlayer insulating film 15′ beneath the interconnect 17 may include an SiO₂ film, and a portion of the interlayer insulating film 15′ above the interconnect 17 may include an SiOC film. Furthermore, the interlayer insulating film 15′ and the element-separating insulating film 23′ may be applied to the solid-state image capturing device according to the first embodiment.

### (3) Third Modification

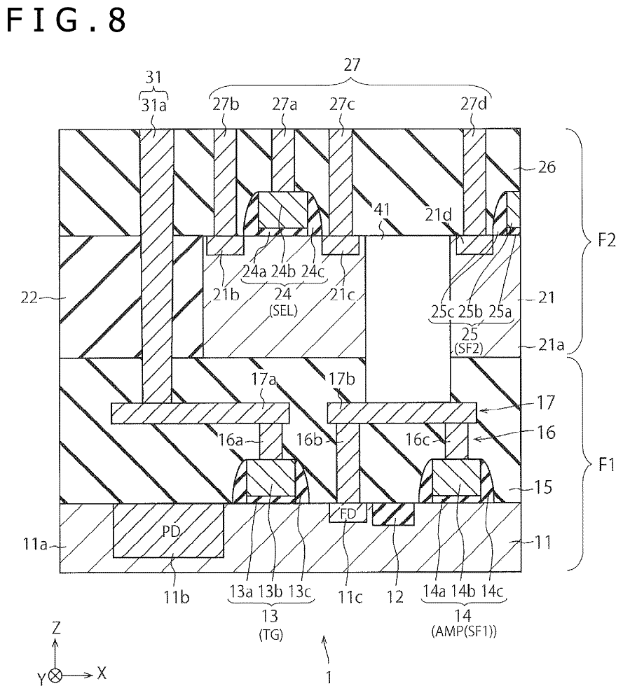

FIG. 8 is a cross-sectional view illustrating a structure of a solid-state image capturing device according to a third modification of the first embodiment.

The solid-state image capturing device (FIG. 8) according to the present modification includes similar components to those of the solid-state image capturing device (FIG. 5) according to the first modification. However, the solid-state image capturing device according to the present modification includes a hollow region 41 instead of the element-separating insulating film 23. The hollow region 41 according to the present modification is filled with air and is held in contact with the upper surface of the interconnect 16b.

The interconnect 17b according to the present modification is disposed in a position superposed on the hollow region 41 as viewed in plan. According to the present modification, therefore, it is possible to restrain the parasitic capacitance between the interconnect 17b and the substrate 21. The hollow region 41 acts like an insulating film having a relative dielectric constant of 1. According to the present modification, consequently, as with the second modification, it is possible to further restrain a parasitic capacitance acting on the interconnect 17b.

As described above, the solid-state image capturing device according to the present embodiment includes in the first floor the pixel transistor 14 (the amplifying transistor AMP) that is electrically connected to the floating diffuser FD. According to the present embodiment, therefore, it is possible to appropriately lay out the pixel transistor 14 for reducing a parasitic capacitance acting on the interconnect 17b for the pixel transistor 14, for example.

### Second Embodiment

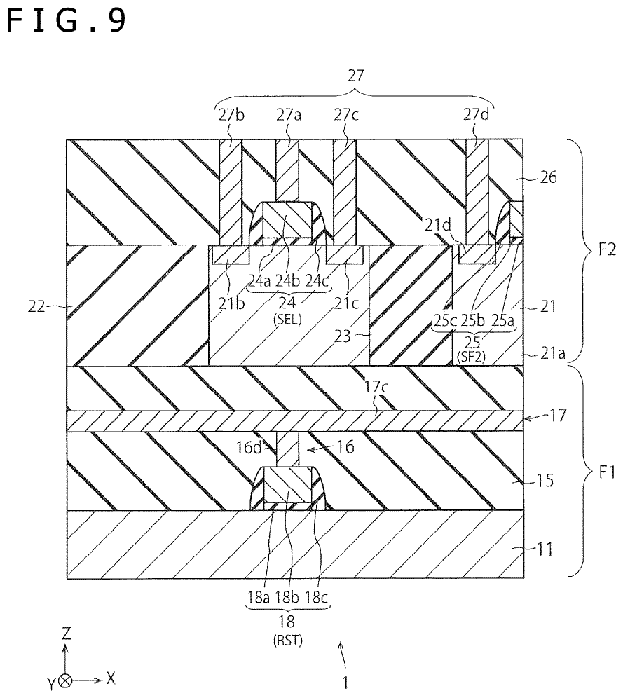

FIG. 9 is a cross-sectional view illustrating a structure of a solid-state image capturing device according to a second embodiment.

The solid-state image capturing device (FIG. 9) according to the present embodiment includes similar components to those of the solid-state image capturing device (FIG. 5) according to the first modification of the first embodiment. However, the solid-state image capturing device according to the present embodiment includes, in addition of the components of the solid-state image capturing device according to the first embodiment, a plug 16d included in the contact plug 16, an interconnect 17c included in the interconnect layer 17, and a pixel transistor 18. The interconnect 17c and the pixel transistor 18 represent an example of a third interconnect and a fourth transistor, respectively, according to the present disclosure.

The pixel transistor 18 includes a gate insulating film 18a and a gate electrode 18b that are successively formed on the substrate 11 and side-wall insulating films 18c formed on both sides of the gate electrode 13b. The gate insulating film 18a includes an SiO₂ film, for example. The gate electrode 18b includes an N-type semiconductor layer (e.g., a polysilicon layer), for example. The side-wall insulating films 18c include SiO₂ films and/or SiN (silicon nitride) films, for example. The pixel transistor 18 includes a resetting transistor RST, for example.

The plug 16d is disposed on the gate electrode 18b. The plug 16d includes an N-type semiconductor layer (e. g., a polysilicon layer), for example. The interconnect 17c is disposed on the plug 16d. The interconnect 17c includes an N-type semiconductor layer (e.g., a polysilicon layer), for example.

The through plug 31 according to the present embodiment is not disposed on the interconnect 17c. With this configuration, a parasitic capacitance caused by the through plug 31 can thus be restrained from acting on the interconnect 17c. In this manner, the pixel transistor 18 and the interconnect 17c according to the present embodiment are disposed so as to be able to restrain a parasitic capacitance as with the pixel transistor 14 and the interconnect 17b according to the first embodiment.

The interconnect 17c according to the present embodiment, as with the interconnect 17b according to the first embodiment, is disposed in a position superposed on the element-separating insulating film 23 as viewed in plan. Moreover, the element-separating insulating film 23 according to the present embodiment extends through the substrate 21, as with the element-separating insulating film 23 according to the first modification of the first embodiment. According to the present embodiment, therefore, it is possible to restrain a parasitic capacitance acting on the interconnect 17c.

FIG. 10 depicts plan views illustrating the structures of the solid-state image capturing device according to the second embodiment. A and B in FIG. 10 illustrate, in a simplified fashion, the structure in the first floor and the structure in the second floor of a pixel 1 in the solid-state image capturing device according to the present embodiment.

A and B in FIG. 10 correspond respectively to A and B in FIG. 4. However, B in FIG. 10 illustrates the element-separating insulating film 23 that is not illustrated in A in FIG. 4 for the sake of convenience. As illustrated in A and B in FIG. 10, the interconnect 17c according to the present embodiment is disposed in a position superposed on the element-separating insulating film 23 as viewed in plan.

According to the present embodiment, as with the first embodiment, it is possible to appropriately lay out the pixel transistor 18 for reducing a parasitic capacitance acting on the interconnect 17c for the pixel transistor 18, for example. Note that the pixel transistor 18 may include a transistor other than the resetting transistor RST, e.g., a transfer transistor TG.

### Third Embodiment

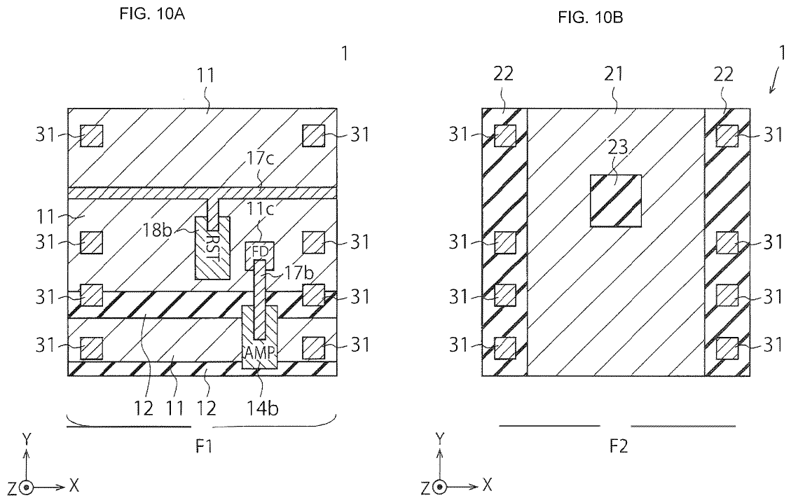

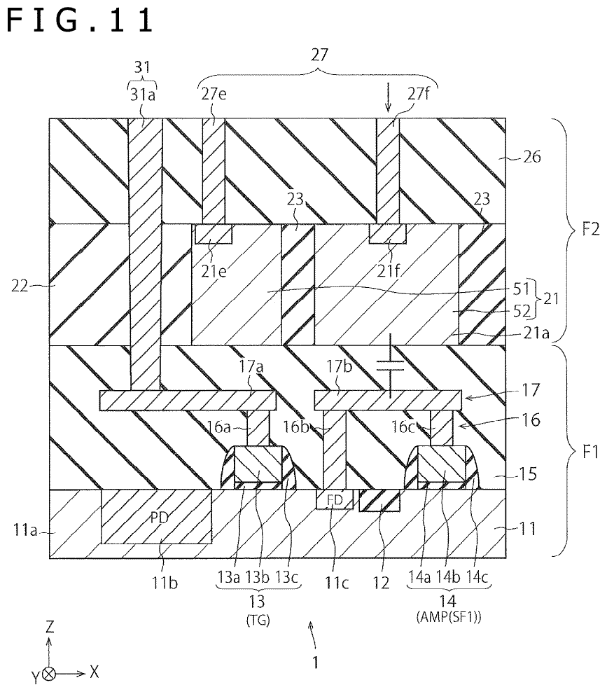

FIG. 11 is a cross-sectional view illustrating a structure of a solid-state image capturing device according to a third embodiment.

The solid-state image capturing device (FIG. 11) according to the present embodiment includes similar components to those of the solid-state image capturing device (FIG. 5) according to the first modification of the first embodiment. However, a substrate 21 according to the present embodiment includes substrate portions 51 and 52 that are separate from each other. Furthermore, a contact plug 27 according to the present embodiment includes a plug 27e formed on a diffusion region 21e in the substrate portion 51 and a plug 27f formed on a diffusion region 21f in the substrate portion 52. The substrate portion 52 and the plug 27f represent an example of a first portion and a second plug, respectively, according to the present disclosure.

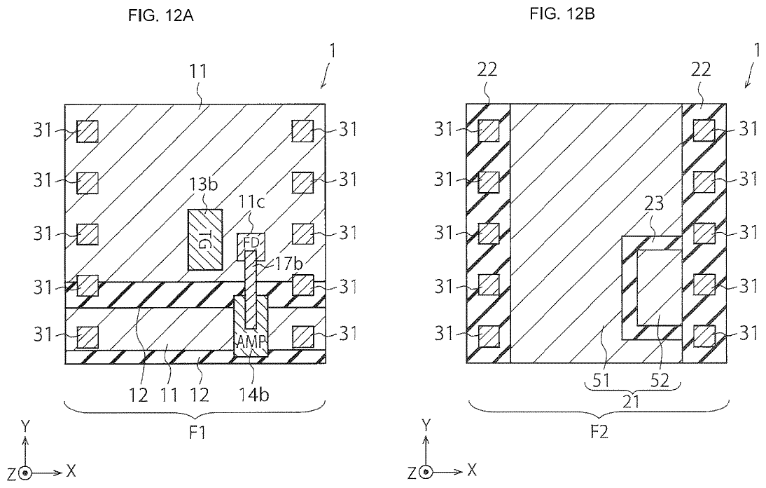

According to the present embodiment, the substrate portion 51 takes up much of the substrate 21, and the substrate portion 52 is smaller than the substrate portion 51. As described later, the substrate portion 52 is annularly surrounded by an insulating film 22 and an element-separating insulating film 23 (B in FIG. 12). The insulating film 22 and the element-separating insulating film 23 according to the present embodiment represent an example of a fifth insulating film according to the present disclosure. The plug 27f is used to control the potential of the substrate portion 52 as schematically indicated by the arrow in FIG. 11.

The interconnect 17c according to the present embodiment is disposed in a position superposed on the substrate portion 52 as viewed in plan. According to the present embodiment, it is possible to control a parasitic capacitance acting on the interconnect 17c by controlling the potential of the substrate portion 52 with the plug 27f. For example, it is possible to reduce the parasitic capacitance acting on the interconnect 17c by controlling a desired potential to apply to the substrate portion 52 with the plug 27f.

FIG. 12 depicts plan views illustrating the Structures of the solid-state image capturing device according to the third embodiment. A and B in FIG. 12 illustrate, in a simplified fashion, the structure in the first floor and the structure in the second floor of a pixel 1 in the solid-state image capturing device according to the present embodiment.

A and B in FIG. 12 correspond respectively to A and B in FIG. 4. However, B in FIG. 12 illustrates the element-separating insulating film 23 that is not illustrated in A in FIG. 4 for the sake of convenience. As illustrated in B in FIG. 12, the substrate portion 52 is annularly surrounded by the insulating film 22 and the element-separating insulating film 23. Moreover, as illustrated in A and B in FIG. 12, the interconnect 17c according to the present embodiment is disposed in a position superposed on the substrate portion 52 as viewed in plan.

According to the present embodiment, as with the first and second embodiments, it is possible to appropriately lay out the pixel transistor 14 for reducing a parasitic capacitance acting on the interconnect 17b for the pixel transistor 14, for

### Fourth Embodiment

FIG. 13 depicts circuit diagrams illustrating the configurations of a solid-state image capturing device according to a fourth embodiment. A and B in FIG. 13 illustrate two examples of the configuration of the solid-state image capturing device according to the present embodiment.

According to the example illustrated in A in FIG. 13, each pixel 1 includes in the first floor a photodiode PD, a floating diffuser FD, a transfer transistor TG, a resetting transistor RST, an amplifying transistor AMP, and a conversion-efficiency switching transistor FDG.

The conversion-efficiency switching transistor FDG functions as a switch for switching between conversion efficiencies for the photoelectric conversion performed by the photodiode PD. One of the source and drain of the conversion-efficiency switching transistor FDG is electrically connected to the floating diffuser FD and the other of the source and drain of the conversion-efficiency switching transistor FDG is electrically connected to the resetting transistor RST. Therefore, the conversion-efficiency switching transistor FDG is disposed between the floating diffuser FD and the resetting transistor RST.

According to the example illustrated in B in FIG. 13, each pixel 1 also includes a photodiode PD, a floating diffuser FD, a transfer transistor TG, a resetting transistor RST, an amplifying transistor AMP, and a conversion-efficiency switching transistor FDG.

However, the resetting transistor RST illustrated in B in FIG. 13 is disposed in the second floor, not the first floor.

According to the present embodiment, it is possible to electrically connect the resetting transistor RST to the floating diffuser FDG through the conversion-efficiency switching transistor FDG, thereby making it possible to switch between conversion efficiencies for the photoelectric conversion performed by the photodiode PD.

### Fifth Embodiment

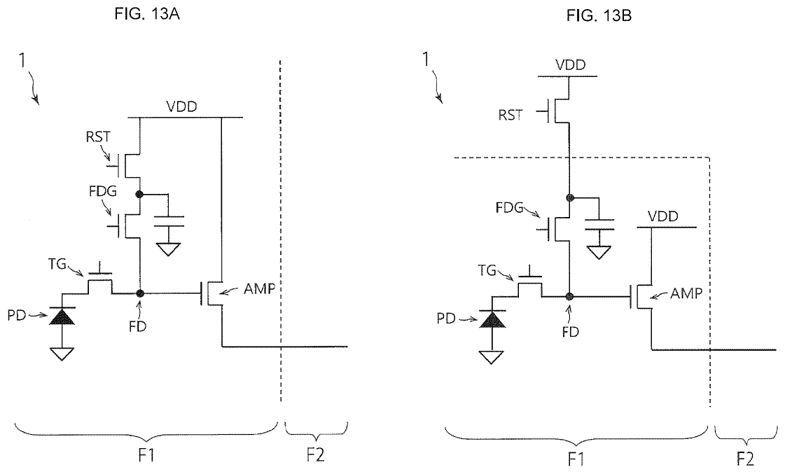

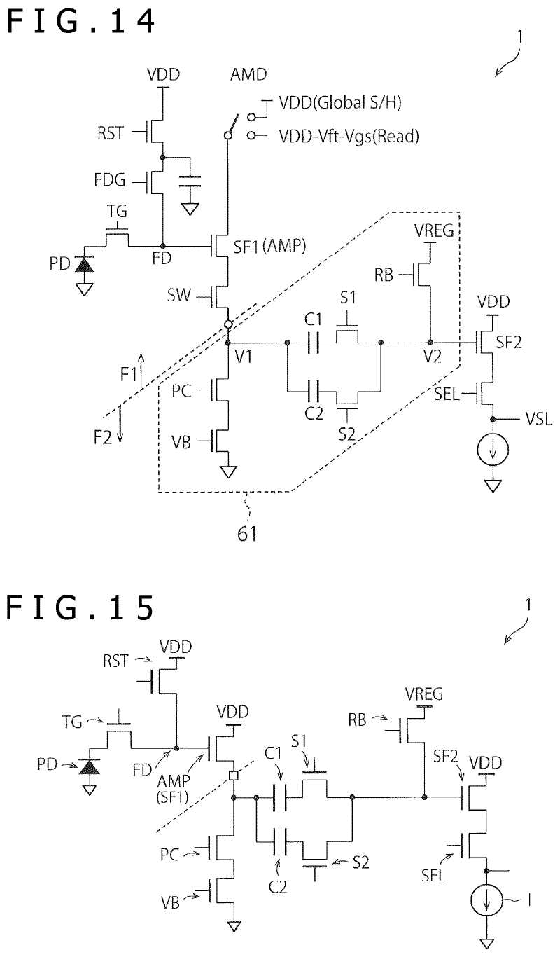

FIG. 14 is a circuit diagram illustrating the configuration of a solid-state image capturing device according to a fifth embodiment.

As with the fourth embodiment, each pixel 1 according to the present embodiment includes in the first floor a photodiode PD, a floating diffuser FD, a transfer transistor TG, a resetting transistor RST, an amplifying transistor SF1 (AMP), and a conversion-efficiency switching transistor FDG. Each pixel 1 according to the present embodiment further includes a switching transistor SW in the first floor. Moreover, each pixel 1 according to the present embodiment includes in the second floor a current-source transistor PC, a rear-stage current-source transistor VB, capacitors C1 and C2, switching transistors S1 and S2, and a VREG voltage transistor RB, which make up a sample and hold circuit 61. Each pixel 1 according to the present embodiment further includes a rear-stage amplifying transistor SF2 and a selection transistor SEL. The solid-state image capturing device according to the present embodiment serves as a voltage-domain CIS (VD-GS) for performing a global shutter function by converting electric charges generated by the photodiode PD simultaneously at all the pixels 1 to voltages and holding the voltages until the reading of the voltages is completed.

The switching transistor SW is able to electrically connect the amplifying transistor SF1 and the capacitors C1 and C2 to each other. When the switching transistor SW is turned on, the amplifying transistor SF1 and the capacitors C1 and C2 are electrically connected to each other. When the switching transistor SW is turned off, the amplifying transistor SF1 and the capacitors C1 and C2 are electrically isolated from each other. One of the source and drain of the switching transistor SW is electrically connected to the amplifying transistor SF1 and the other the source and drain of the switching transistor SW is electrically connected to the current source transistor PC and the capacitors C1 and C2.

The capacitors C1 and C2 are electrically connected to a node V1 between the switching transistor SW and the current-source transistor PC. One electrode of the capacitor Cl is electrically connected to the node V1 and the other electrode of the capacitor C1 is electrically connected to the switching transistor S1. One electrode of the capacitor C2 is electrically connected to the node V1 and the other electrode of the capacitor C2 is electrically connected to the switching transistor S2. The capacitors C1 and C2 are connected parallel to each other.

The switching transistor S1 is able to electrically connect the capacitor C1 and the rear-stage amplifying transistor SF2 to each other. When the switching transistor S1 is turned on, the capacitor Cl and the rear-stage amplifying transistor SF2 are electrically connected to each other. When the switching transistor S1 is turned off, the capacitor C1 and the rear-stage amplifying transistor SF2 are electrically isolated from each other. One of the source and drain of the switching transistor S1 is electrically connected to the capacitor C1 and the other of the source and drain of the switching transistor S1 is electrically connected to the VREG voltage transistor RB and the rear-stage amplifying transistor SF2.

The switching transistor S2 is able to electrically connect the capacitor C2 and the rear-stage amplifying transistor SF2 to each other. When the switching transistor $2 is turned on, the capacitor C2 and the rear-stage amplifying transistor SF2 are electrically connected to each other. When the switching transistor S2 is turned off, the capacitor C2 and the rear-stage amplifying transistor SF2 are electrically isolated from each other. One of the source and drain of the switching transistor S2 is electrically connected to the capacitor C2 and the other of the source and drain of the switching transistor S2 is electrically connected to the VREG voltage transistor RB and the rear-stage amplifying transistor SF2.

The VREG voltage transistor RB is electrically connected to a node V2 between the switching transistors S1 and S2 and the rear-stage amplifying transistor SF2. When the VREG voltage transistor RB is turned on, a VREG voltage is applied therethrough to the node V2.

The rear-stage amplifying transistor SF2 receives the electric charges output from the capacitors C1 and C2 at its gate and outputs the electric charges to a vertical signal line 8 (VSL) via a source follower. The gate of the rear-stage amplifying transistor SF2 is electrically connected to the capacitors C1 and C2 and the VREG voltage transistor RB. One of the source and drain of the rear-stage amplifying transistor SF2 is electrically connected to the power source voltage and the other of the source and drain of the rear-stage amplifying transistor SF2 is electrically connected to the selection transistor SEL.

The selection transistor SEL is able to electrically connect the rear-stage amplifying transistor SF2 and the vertical signal line 8 to each other. When the selection transistor SEL is turned on, the rear-stage amplifying transistor SF2 and the vertical signal line 8 are electrically connected to each other. When the selection transistor SEL is turned off, the rear-stage amplifying transistor SF2 and the vertical signal line 8 are electrically isolated from each other. One of the source and drain of the selection transistor SEL is electrically connected to the rear-stage amplifying transistor SF2 and the other of the source and drain of the selection transistor SEL is electrically connected to the vertical signal line 8.

The current-source transistor PC and the rear-stage current-source transistor VB function as a current source. One of the source and drain of the current-source transistor PC is electrically connected to the switching transistor SW and the other of the source and drain of the current-source transistor PC is electrically connected to the rear-stage current-source transistor VB. One of the source and drain of the rear-stage current-source transistor VB is electrically connected to the current-source transistor PC.

According to the present embodiment, the sample and hold circuit 61 provided in the second floor makes it possible to perform a global shutter function, for example.

### Sixth Through Tenth Embodiments

FIG. 15 is a circuit diagram illustrating the configuration of a solid-state image capturing device according to a sixth embodiment.

A pixel 1 illustrated in FIG. 15 has a configuration similar to the pixel 1 illustrated in FIG. 14 except that the conversion-efficiency switching transistor FDG and the switching transistor SW are excluded. Therefore, the configuration is effective to reduce the number of transistors in each pixel 1.

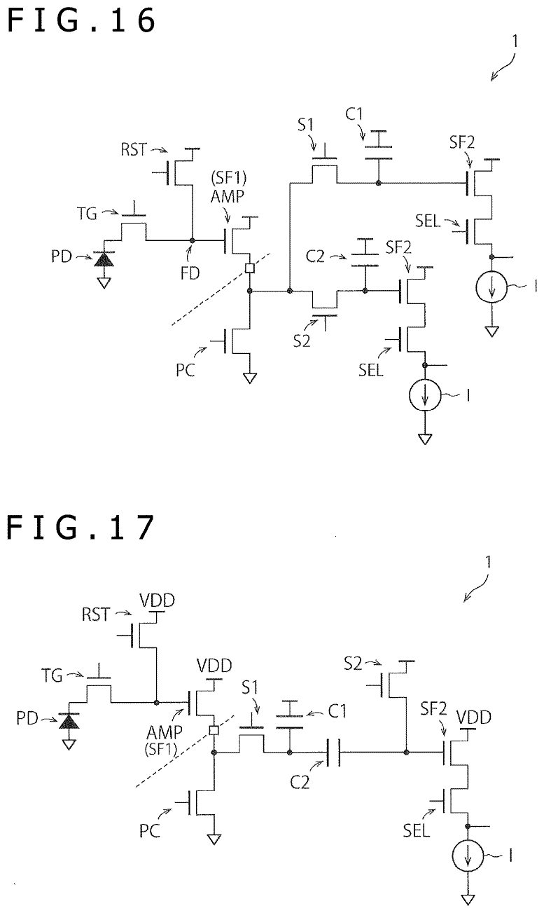

FIG. 16 is a circuit diagram illustrating the configuration of a solid-state image capturing device according to a seventh embodiment.

A pixel 1 illustrated in FIG. 16 is of a configuration similar to the pixel 1 illustrated in FIG. 15 except that it includes another rear-stage amplifying transistor SF2 and another selection transistor SEL instead of the rear-stage current-source transistor VB and the VREG voltage transistor RB. The pixel 1 illustrated in FIG. 16 includes, in a rear stage following the amplifying transistor AMP, a circuit section that includes a switching transistor S1, a capacitor C1, a rear-stage amplifying transistor SF2, and a selection transistor SEL and a circuit section that includes a switching transistor S2, a capacitor C2, a rear-stage amplifying transistor SF2, and a selection transistor SEL.

FIG. 17 is a circuit diagram illustrating the configuration of a solid-state image capturing device according to an eighth embodiment.

A pixel 1 illustrated in FIG. 17 is of a configuration similar to the pixel 1 illustrated in FIG. 15 except that the rear-stage current-source transistor VB and the VREG voltage transistor RB are excluded. Moreover, in FIG. 17, the switching transistor S1 is disposed in a rear stage following the amplifying transistor AMP and the capacitor C2 is disposed between the amplifying transistor AMP and the rear-stage amplifying transistor SF2. Furthermore, in FIG. 17, the capacitor Cl is electrically connected to a node between the switching transistor S1 and the capacitor C2 and the switching transistor S2 is electrically connected to a node between the capacitor C2 and the rear-stage amplifying transistor SF2.

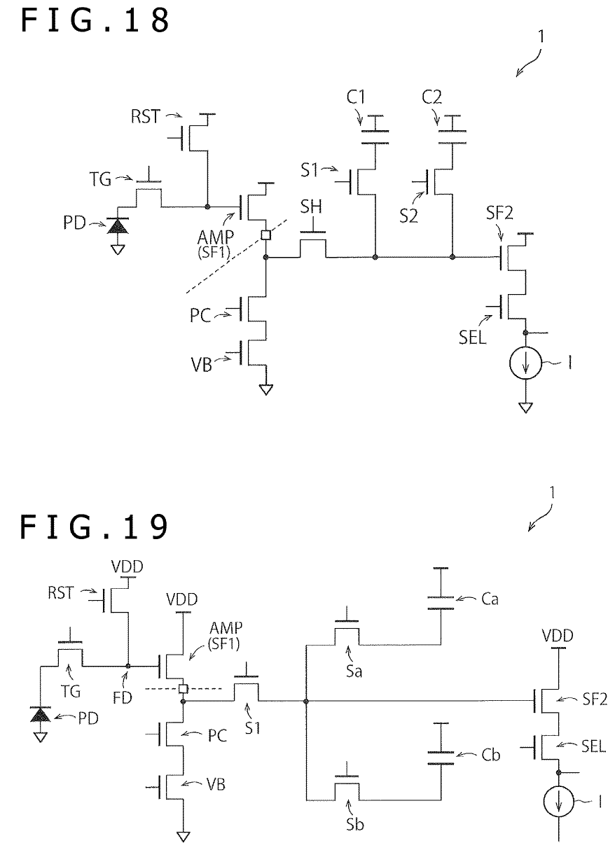

FIG. 18 is a circuit diagram illustrating the configuration of a solid-state image capturing device according to a ninth embodiment.

A pixel illustrated in FIG. 18 has a configuration similar to the pixel 1 illustrated in FIG. 15 except that it includes a switching transistor SH instead of the VREG voltage transistor RB. The switching transistor SH is disposed in a rear stage following the amplifying transistor AMP. In FIG. 18, furthermore, the switching transistors S1 and S2 are electrically connected to respective nodes between the switching transistor SH and the rear-stage amplifying transistor SF2 (parallel connection). The capacitors C1 and C2 are disposed in rear stages following the switching transistors S1 and S2, respectively.

FIG. 19 is a circuit diagram illustrating the configuration of a solid-state image capturing device according to a tenth embodiment.

A pixel 1 illustrated in FIG. 19 has a configuration similar to the pixel 1 illustrated in FIG. 15 except that it includes capacitors Ca and Cb and switching transistors Sa and Sb instead of the capacitors C1 and C2, the switching transistor S2, and the VREG voltage transistor RB. The switching transistor S1 is disposed between the amplifying transistor AMP and the rear-stage amplifying transistor SF2. The capacitor Ca and the switching transistor Sa are disposed in series with each other in a rear stage following a node between the switching transistor S1 and the rear-stage amplifying transistor SF2. Likewise, the capacitor Cb and the switching transistor Sb are disposed in series with each other in a rear stage following the node between the switching transistor S1 and the rear-stage amplifying transistor SF2.

According to the sixth through tenth embodiments, it is possible to provide the pixels 1 in the solid-state image capturing device in various configurations. The configurations according to the sixth through tenth embodiments may be applied to the pixels 1 according to any of the first through fourth embodiments.

### Eleventh Embodiment

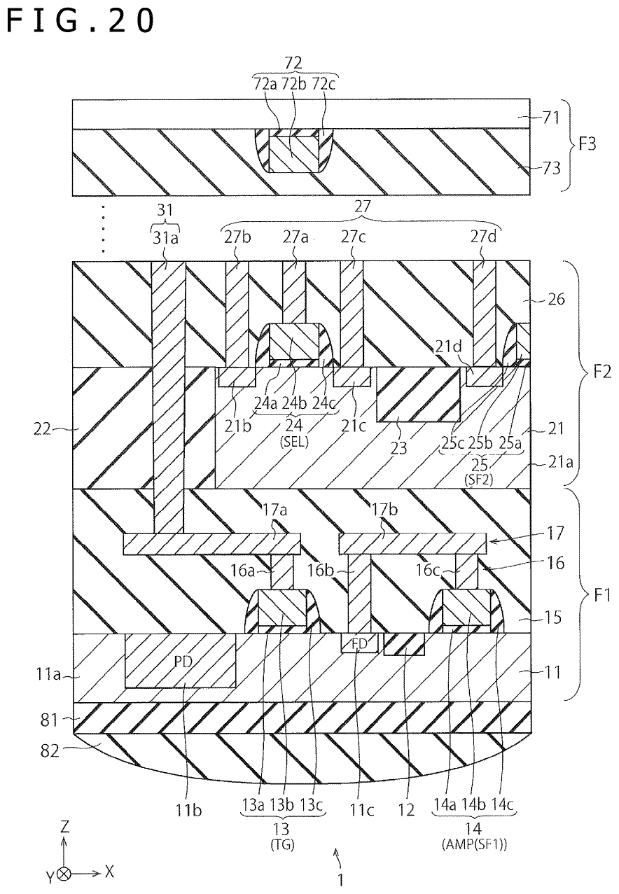

FIG. 20 is a cross-sectional view illustrating a structure of a solid-state image capturing device according to an eleventh embodiment. FIG. 20 illustrates one pixel 1 in the solid-state image capturing device according to the present embodiment, as with FIG. 2 and other figures.

The solid-state image capturing device according to the present embodiment includes, in addition to the components illustrated in FIG. 2, an on-chip filter 81, an on-chip lens 82, a substrate 71, a transistor 62, and an interlayer insulating film 73.

In FIG. 20, the upper surface of the substrate 11 represents a face side of the substrate 11 and the lower surface of the substrate 11 represents a reverse side of the substrate 11. The solid-state image capturing device according to the present embodiment is of the back-illuminated type where the lower surface (the reverse side) of the substrate 11 acts as a light incidence surface (light-detecting surface).

In FIG. 20, the pixel transistor 13 and the pixel transistor 14 are formed on the upper surface of the substrate 11, whereas the on-chip filter 81 and the on-chip lens 82 are formed on the lower surface of the substrate 11. Specifically, the on-chip filter 81 and the on-chip lens 82 are successively formed beneath the substrate 11.

The on-chip filter 81 acts to transmit light at a predetermined wavelength therethrough and is formed on the upper surface of the substrate 11 in each of the pixels 1. For example, on-chip filters 81 for red (R), green (G), and blue (B) are disposed below the respective photodiodes PD of pixels 1 for red, green, and blue. Moreover, an on-chip filter 81 for infrared light may be disposed below the photodiode PD of a pixel 1 for infrared light.

The on-chip lens 82 acts to focus light that is incident thereon and is formed beneath the on-chip filter 81 in each of the pixels 1. According to the present embodiment, light that is incident on the on-chip lens 82 is focused thereby, passes through the on-chip filter 81, and is applied to the photodiode PD. The photodiode PD converts the light to electric charges by way of photoelectric conversion, generating signal electric charges.

The substrate 71 is disposed above the substrate 21. The substrate 71 includes a semiconductor substrate such as an Si substrate, for example. In FIG. 20, the X direction and the Y direction extend parallel to the lower surface of the substrate 71 and the Z direction extends perpendicularly to the lower surface of the substrate 71.

The transistor 72 includes a gate insulating film 62a and a gate electrode 62b that are successively formed beneath the substrate 71 and side-wall insulating films 62c formed on both sides of the gate electrode 62b. The gate insulating film 62a includes an SiO₂ film, for example. The gate electrode 62b includes an N-type semiconductor layer (e.g., a polysilicon layer), for example. The side-wall insulating films 62c include SiO₂ films and/or SiN films, for example. The transistor 72 makes up a logic circuit of the solid-state image capturing device according to the present embodiment, for example.

The interlayer insulating film 73 is formed beneath the substrate 71 and the transistor 72 in covering relation to the transistor 72. The interlayer insulating film 73 includes, for example, a layered insulating film including an SiO₂ film and other insulating films. According to the present embodiment, the interlayer insulating film 73 is formed on the interlayer insulating film 26 and has a lower surface held in contact with the upper surface of the interlayer insulating film 24. The substrate 71 is affixed to the substrate 21 with the interlayer insulating films 73 and 26 interposed therebetween.

As described above, the solid-state image capturing device according to the present embodiment is of a three-layer structure including the substrate 11 (first layer), the substrate 21 (second layer), and the substrate 71 (third layer). Whereas regions in the substrate 11 and the interlayer insulating film 14 are called the “first floor” and regions in the substrate 21 and the interlayer insulating film 24 are called the “second floor,” regions in the substrate 71 and the interlayer insulating film 73 are called a “third floor.” For example, the photodiode PD, the floating diffuser FD, and the pixel transistors 13 and 14 are disposed in the first floor, the pixel transistors 24 and 25 are disposed in the second floor, and the transistor 72 is disposed in the third floor. Furthermore, the through plugs 31 extend across and over the first floor and the second floor. In FIG. 20, the first floor, the second floor, and the third floor are denoted by F1, F2, and F3, respectively.

According to the present embodiment, it is possible to reduce the number of transistors disposed in the first layer and the second layer, for example, by applying a three-layer structure to the solid-state image capturing device. It is thus possible to reduce the area of each pixel 1 as viewed in plan and to reduce the size (area) of the solid-state image capturing device as viewed in plan.

Note that the structures of the first, second, and third floors according to the present embodiment may be different from the structures illustrated in FIG. 20. For example, some of the components in the first floor illustrated in FIG. 20 may be relocated to the second floor or the third floor. This holds true also for the components in the second floor illustrated in FIG. 20 and the components in the third floor illustrated in FIG. 20.

### Applications

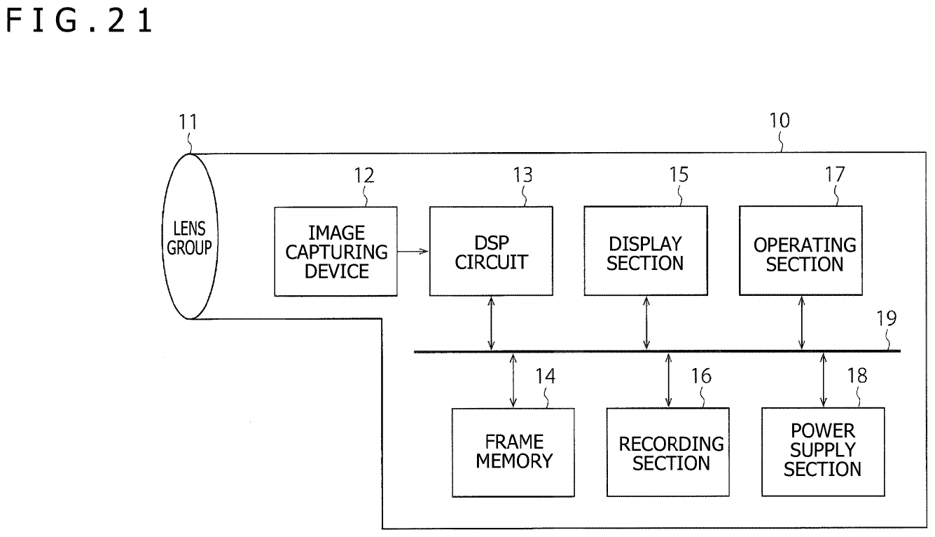

FIG. 21 is a block diagram illustrating a configurational example of an electronic device. The electronic device illustrated in FIG. 21 is a camera 100.

The camera 100 includes an optical system 101 including a lens group, an image capturing device 102 that includes the solid-state image capturing device according to either one of the first through fourteenth embodiments, a DSP (Digital Signal Processor) circuit 103 as a camera signal processing circuit, a frame memory 104, a display section 105, a recording section 106, an operating section 107, and a power source section 108. Furthermore, the DSP circuit 103, the frame memory 104, the display section 105, the recording section 106, the operating section 107, and the power source section 108 are connected to each other by a bus line 109.

The optical system 101 acquires incident light (image light) from a subject and focuses the incident light onto an image capturing surface of the image capturing device 102. The image capturing device 102 converts the amount of the incident light that has been focused on the image capturing surface by the optical system 101 to an electric signal per pixel and outputs the electric signal as a pixel signal.

The DSP circuit 103 performs signal processing on the pixel signal output from the image capturing device 102. The frame memory 104 includes a memory for storing one frame of a moving image or still image captured by the image capturing device 102.

The display section 105 includes a panel-type display device such as a liquid crystal panel or an organic EL panel, for example, and displays the moving image or still image captured by the image capturing device 102. The recording section 106 records the moving image or still image captured by the image capturing device 102 into a recording medium such as a hard disk or a semiconductor memory, for example.

The operating section 107 issues operation commands with regard to various functions of the camera 100 when it is operated by a user. The power source section 108 appropriately supplies the DSP circuit 103, the frame memory 104, the display section 105, the recording section 106, and the operating section 107 with various power sources as operation power sources for those supply targets.

By using either one of the solid-state image capturing devices according to the first through fourteenth embodiments as the image capturing device 102, the image capturing device 102 can be expected to acquire satisfactory images.

The solid-state image capturing device is applicable to various other products. For example, the solid-state image capturing device may be incorporated in various mobile objects such as automobiles, electric vehicles, hybrid electric vehicles, motorcycles, bicycles, personal mobility devices, airplanes, drones, ships, and robots, for example,

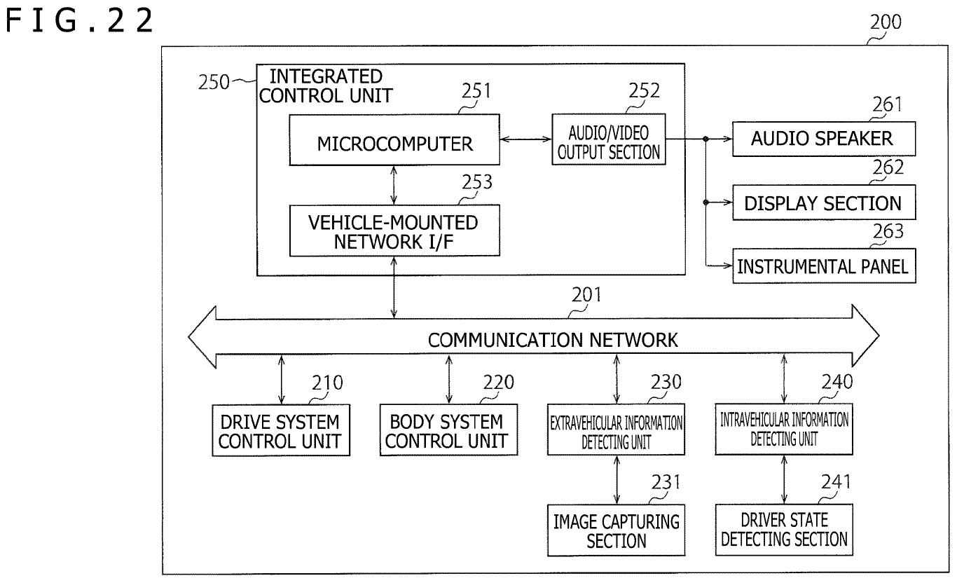

FIG. 22 is a block diagram illustrating a configurational example of a mobile body control system. The mobile body control system illustrated in FIG. 22 includes a vehicle control system 200.

The vehicle control system 200 includes multiple electronic control units connected to each other by a communication network 201. According to the example illustrated in FIG. 22, the vehicle control system 200 includes a drive system control unit 210, a body system control unit 220, an extravehicular information detecting unit 230, an intervehicular information detecting unit 240, and an integrated control unit 250. FIG. 22 further illustrates a microcomputer 251, an audio/video output section 252, and a vehicle-mounted network I/F (Interface) 253 as components of the integral control unit 250.

The drive system control unit 210 controls operation of devices relative to a vehicle drive system. For example, the drive system control unit 210 functions as a control device for controlling a drive power generating device for generating drive power for a vehicle such as an internal combustion engine or a drive motor, a drive power transmitting mechanism for transmitting the drive power to wheels, a steering mechanism for adjusting the steering angle of the vehicle, and a braking device for generating braking forces for the vehicle.

The body system control unit 220 controls operation of various devices incorporated in the body of the vehicle according to various programs. For example, the body system control unit 220 functions as a controller for a smart key system, a keyless entry system, a power window device, and various lamps (e.g., head lamps, rear lamps, brake lamps, winkers, and fog lamps) and the like. In this case, the body system control unit 220 can be supplied with radio waves transmitted from a portable unit that replaces a key and signals from various switches. In response to such radio waves or signals, the body system control unit 220 controls the door lock device, the power window device, and the lamps, for example.

The extravehicular information detecting unit 230 detects information regarding the exterior of a vehicle that incorporates the vehicle control system 200. An image capturing section 231, for example, is connected to the extravehicular information detecting unit 230. The extravehicular information detecting unit 230 controls the image capturing section 231 to capture an image of the exterior of the vehicle and receives the captured image from the image capturing section 231. The extravehicular information detecting unit 230 may perform an object detecting process for detecting objects such as persons, vehicles, obstacles, signs, and characters on roads, for example, or a distance detecting process on the basis of the received image.

The image capturing section 231 includes an optical sensor for detecting light and outputting an electric signal representing the amount of the detected light. The image capturing section 231 can output the electric signal as an image or output the electric signal as information of a measured distance. The light that is detected by the image capturing section 231 may be visible light or nonvisible light such as an infrared radiation. The image capturing section 231 includes the solid-state image capturing device according to either one of the first through fourteenth embodiments.

The intervehicular information detecting unit 240 detects information regarding the interior of a vehicle that incorporates the vehicle control system 200. A driver state detecting section 241 for detecting the state of the driver, for example, is connected to the intervehicular information detecting unit 240. The driver state detecting section 241 includes a camera for capturing an image of the driver, for example. The intervehicular information detecting unit 240 may calculate the degree of fatigue of the driver or the degree of concentration of the driver or may decide whether the driver is nodding off or not on the basis of the detected information input from the driver state detecting section 241. The camera may include the solid-state image capturing device according to either one of the first through fourteenth embodiments or the camera 100 illustrated in FIG. 21, for example.

The microcomputer 251 can calculate a control target value for the drive power generating device, the steering mechanism, or the braking device on the basis of the information of the exterior or interior of the vehicle acquired by the extravehicular information detecting unit 230 or the intervehicular information detecting unit 240, and output control commands to the drive system control unit 210. For example, the microcomputer 251 performs cooperative control for achieving the functions of an ADAS (Advanced Driver Assistance System) including vehicle collision avoidance, impact reduction, cruise control driving based on an intervehicular distance, constant speed driving, collision warning, and lane departure warning, for example.

Moreover, the microcomputer 251 can control the drive power generating device, the steering mechanism, or the braking device on the basis of the information of the periphery of the vehicle acquired by the extravehicular information detecting unit 230 or the intervehicular information detecting unit 240, thereby performing cooperative control for the purpose of automatic driving to achieve autonomous driving without the intervention of the driver.

Furthermore, the microcomputer 251 can output control commands to the body system control unit 220 on the basis of the information of the exterior of the vehicle acquired by the extravehicular information detecting unit 230. For example, the microcomputer 251 can control the head lamps depending on the position of a leading or oncoming vehicle detected by the extravehicular information detecting unit 230 for performing cooperative control for the purpose of taking an anti-glare action to switch from a high beam to a low beam, for example.

The audio/video output section 252 transmits an output signal representing at least one of sound and image to an output device that is capable of notifying vehicle occupants or the exterior of the vehicle of visual or aural information. According to the example illustrated in FIG. 22, the output device includes an audio speaker 261, a display section 262, and an instrumental panel 263. The display section 262 may include an on-board display or a head-up display, for example.

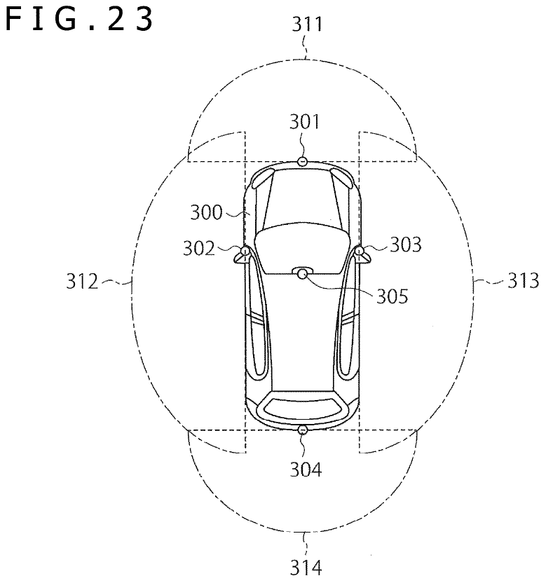

FIG. 23 is a plan view illustrating a specific example of set positions of the image capturing section 231 illustrated in FIG. 22.

A vehicle 300 illustrated in FIG. 23 includes image capturing sections 301, 302, 303, 304, and 305 as the image capturing section 231. The image capturing sections 301, 302, 303, 304, and 305 are provided in respective positions on a front nose, side mirrors, a rear bumper or a back door, and an upper portion of the front windshield within the passenger compartment of the vehicle, for example.

The image capturing section 301 on the front nose mainly acquires an image of a front zone ahead of the vehicle 300. The image capturing section 302 on the left side mirror and the image capturing section 303 on the right side mirror mainly acquire images of side zones alongside of the vehicle 300. The image capturing section 304 on the rear bumper or the back door mainly acquires an image of a rear zone behind the vehicle 300. The image capturing section 305 on the upper portion of the front windshield within the passenger compartment mainly acquires an image of the front zone ahead of the vehicle 300. The image capturing section 305 is used to detect a leading car, pedestrians, obstacles, traffic signals, traffic signs, lanes, and the like, for example.

FIG. 23 illustrates an example of image capturing ranges of the image capturing sections 301, 302, 303, and 304 (hereinafter referred to as the “image capturing sections 301 through 304”). An image capturing range 311 refers to the image capturing range of the image capturing section 301 on the front nose. An image capturing ranges 312 refers to the image capturing range of the image capturing section 302 on the left side mirror. An image capturing range 313 refers to the image capturing range of the image capturing section 303 on the right side mirror. An image capturing range 314 refers to the image capturing range of the image capturing section 304 on the rear bumper or back door. Image data captured by the image capturing sections 301 through 304 are superposed to obtain a bird's-eye view of the vehicle 300, i.e., a view of the vehicle 300 from a high position looking down. The image capturing ranges 311, 312, 313, and 314 will hereinafter be referred to as the “image capturing ranges 311 through 314.”

At least one of the image capturing sections 301 through 304 may have a function to acquire distance information. For example, at least one of the image capturing sections 301 through 304 may include a stereo camera including a plurality of image capturing devices or an image capturing device having pixels for detecting a phase difference.

For example, the microcomputer 251 (FIG. 22) calculates distances up to three-dimensional objects in the image capturing ranges 311 through 314 and changes over time in the distances on the basis of the distance information obtained from the image capturing sections 301 through 304. On the basis of the calculated results, the microcomputer 251 can extract as a leading car a closest three-dimensional object traveling on the path of travel of the vehicle 300 in substantially the same direction as the vehicle 300 at a predetermined speed (e. g., 0 km/h or higher) as. Moreover, the microcomputer 251 can establish an intervehicular distance to be secured in advance up to the leading car and can perform an automatic braking control process (including a cruise control stopping process), an automatic acceleration control process (including a cruise control starting process), and the like. Such this, according to this example, it is possible to perform cooperative control for the purpose of automatic driving and the like to achieve autonomous driving without the intervention of the driver.

For example, the microcomputer 251 can classify and extract three-dimensional object data regarding three-dimensional objects as three-dimensional objects such as motorcycles, ordinary vehicles, large-size vehicles, pedestrians, utility poles, and others on the basis of the distance information obtained from the image capturing sections 301 through 304 and use the extracted three-dimensional object data for automatically avoiding obstacles. For example, the microcomputer 251 identifies obstacles in the periphery of the vehicle 300 and distinguishes them as obstacles that are visible by the driver of the vehicle 300 and obstacles difficult for the driver to see. Then, the microcomputer 251 determines a risk of collision representing a level of danger of collision with each of the obstacles, and, if the risk of collision is of a preset value or larger, indicating that the vehicle 300 is in a situation where there is a possibility of collision, outputs a warning to the driver through the audio speaker 261 and the display section 262 and controls the drive system control unit 210 to forcibly decelerate the vehicle 300 or steer the vehicle 300 to avoid the possible collision, so that the microcomputer 251 can perform driving assistance for collision avoidance.

At least one of the image capturing sections 301 through 304 may include an infrared camera for detecting an infrared radiation. For example, the microcomputer 251 can recognize a pedestrian by determining whether or not a pedestrian is present in images captured by the image capturing sections 301 through 304. The microcomputer 251 can recognize a pedestrian by performing a process of extract feature points in the images captured by the image capturing sections 301 through 304 as infrared cameras and a process of performing pattern matching on a series of feature points indicating the contour of an object to determine whether the object is a pedestrian or not. If the microcomputer 251 decides that a pedestrian is present in the images captured by the image capturing sections 301 through 304 and hence recognizes the pedestrian, then the audio/video output section 252 controls the display section 262 to display a square contour line over the recognized pedestrian for emphasis. Furthermore, the audio/video output section 252 may control the display section 262 to display an icon and the like indicative of the pedestrian at a desired

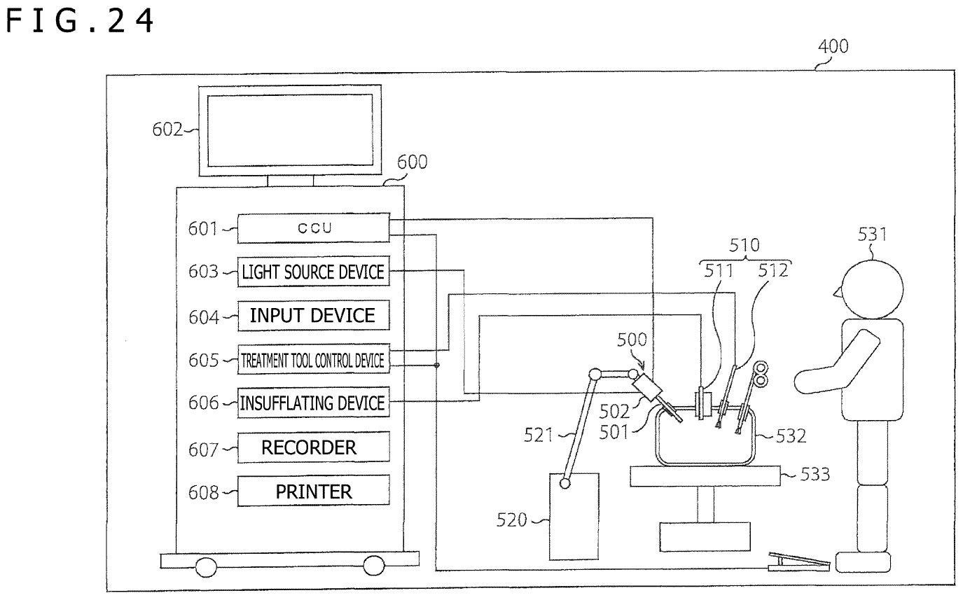

FIG. 24 is a view illustrating a general configurational example of an endoscopic surgical system to which the technology according to the present disclosure (present technology) is applicable.

FIG. 24 illustrates the manner in which a surgeon (doctor) 531 is performing surgery on a patient 532 on a patient bed 533 using an endoscopic surgical system 400. As illustrated in FIG. 24, the endoscopic surgical system 400 includes an endoscope 500, other surgical instruments 510 including an insufflating tube 511 and an energy treatment tool 512, a support arm device 520 that supports the endoscope 500, and a cart 600 housing various devices for endoscopic surgery.

The endoscope 500 includes a lens barrel 501 whose predetermined length from its distal end is inserted into a body cavity in the patient 532 and a camera head 502 connected to the proximal end of the lens barrel 501. Though the endoscope 500 is illustrated as a rigid scope having a rigid lens barrel as the lens barrel 501, the endoscope 500 may be configured as a flexible scope having a flexible lens barrel.

The distal end of the lens barrel 501 has an opening with an objective lens fitted therein. A light source device 603 is connected to the endoscope 500. Light generated by the light source device 603 is introduced through a light guide extending in the lens barrel 501 to the distal end of the lens barrel 501 and passes through the objective lens to irradiate an observation target in the body cavity in the patient 532. Note that the endoscope 500 may include a forward-viewing endoscope, a forward-oblique-viewing endoscope, or a side-viewing endoscope.

The camera head 502 houses therein an optical system and image capturing elements. Reflected light (observed light) from an observation target is focused onto the image capturing elements by the optical system. The image capturing elements photoelectrically convert the observed light to an electric signal representing the observed light, i.e., an image signal representing an observed image. The image signal is transmitted as RAW data to a camera control unit (CCU) 601.

The CCU 601 includes a CPU (Central Processing Unit) or a GPU (Graphics Processing Unit), for example, and integrally controls operation of the endoscope 500 and a display device 602. Moreover, the CCU 601 receives the image signal from the camera head 502 and performs various image processing processes such as an image developing process (pixelating process), for example, on the image signal for displaying an image based on the image signal.

The display device 602 is controlled by the CCU 601 to display an image based on the image signal on which the image processing processes have been performed by the CCU 601.

The light source device 603 includes a light source such as LEDs (Light Emitting Diodes), for example, and supplies the endoscope 500 with illuminating light to be applied for capturing an image of a surgical site.

An input device 604 represents an input interface to the endoscopic surgical system 11000. The user can enter various pieces of information and instructions into the endoscopic surgical system 400 via the input device 604. For example, the user enters an instruction for changing image capturing conditions (types of illuminating light, magnifications, focal lengths, and the like) under which the endoscope 500 captures images.

A treatment tool control device 605 controls energization of the energy treatment tool 512 for cauterizing, incising tissues, sealing blood vessels, and the like. An insufflating device 606 sends a gas through the insufflating tube 511 into the body cavity in the patient 532 to inflate the body cavity for the purposes of securing a field of vision for the endoscope 500 and a space where the surgeon works in the body cavity. A recorder 607 refers to a device for recording various items of information regarding a surgical operation. A printer 608 refers to a device for printing various items of information regarding a surgical operation in various formats including texts, images, or graphs, for example.

Note that the light source device 603 that supplies the endoscope 500 with illuminating light to be applied for capturing an image of a surgical site may include LEDs, laser light sources or a white-light light source including a combination of LEDs and laser light sources, for example. In case the white-light light source includes a combination of RGB laser light sources, since the output intensities and output timings of the respective colors (respective wavelengths) can be controlled to a nicety, the light source device 603 is able to adjust the white balance of captured images. Furthermore, in this case, it is also possible to capture RGB images in a time-division multiplex fashion by illuminating an observation target with respective laser beams from the RGB laser light sources in a time-division multiplex fashion and controlling energization of the image capturing elements of the camera head 502 in synchronism with the timing of the illumination. According to this process, the endoscope 500 is able to obtain color images without color filters provided on the image capturing elements.

Furthermore, the light source device 603 may be controlled in its energization to change the intensity of light output therefrom at predetermined times. In synchronism with the timing of the changes in the intensity of light, the image capturing elements of the camera head 502 may be controlled in their energization to acquire images in a time-division multiplex manner and the acquired images may be combined into an image having a high dynamic range that is free of generally-called crushed shadows and clipped whites.

Furthermore, the light source device 603 may be arranged to be able to supply light in a predetermined wavelength band for special light observations. For example, the special light observations include a narrow band imaging process for capturing a high-contrast image of a body tissue such as a blood vessel in a mucosal surface layer by illuminating the body tissue with light in generally-called a narrower band than illuminating light (e.g., white light) in normal observations, using the wavelength dependency of light absorption by the body tissue. The special light observations may also include a fluorescence observation for obtaining an image by way of fluorescence produced by applying exciting light. According to the fluorescence observation, exciting light may be applied to a body tissue and fluorescence from the body tissue may be observed (autofluorescence observation), or a reagent such as indocyanine green (ICG) may be locally injected into a body tissue and exciting light at the fluorescence wavelength of the reagent may be applied to the body tissue to obtain a fluorescent image, and the like, for example. The light source device 603 can be configured to be able to supply narrow-band light and/or exciting light for such special light observations.

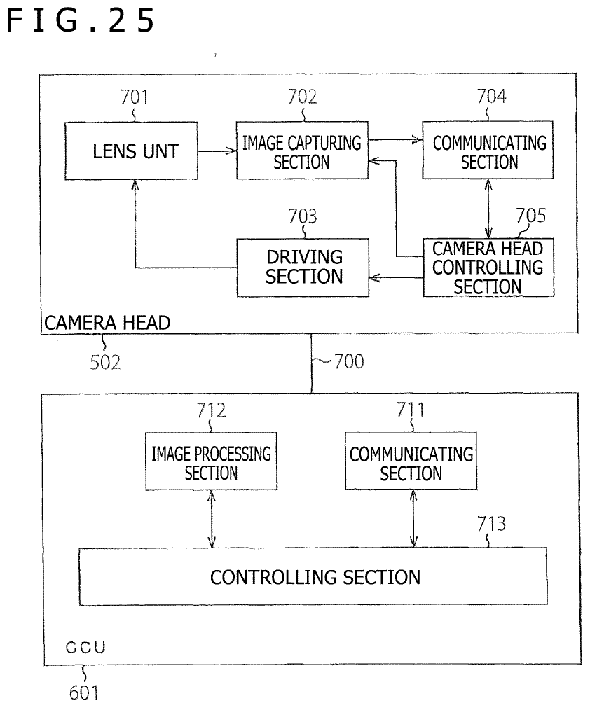

FIG. 25 is a block diagram illustrating an example of functional configurations of the camera head 502 and the CCU 601.

The camera head 502 has a lens unit 701, an image capturing section 702, a driving section 703, a communicating section 704, and a camera head controlling section 705. The CCU 601 has a communicating section 711, an image processing section 712, and a controlling section 713. The camera head 502 and the CCU 601 are connected by a transmission cable 700 for communication with each other.

The lens unit 701 is an optical system provided at the junction to the lens barrel 501. Observed light introduced into the lens barrel 501 from its distal end travels to the camera head 502 where it is applied to the lens unit 701. The lens unit 701 includes a combination of multiple lenses including a zoom lens and a focusing lens.

The image capturing section 702 includes an image capturing element or elements. The image capturing section 702 may include either a single image capturing element (generally-called single-panel type) or a plurality of image capturing units (generally-called multi-panel type). In case the image capturing section 702 is of the multi-panel type, the image capturing elements generate RGB image signals, respectively, for example, that may be combined into a color image. Alternatively, the image capturing section 702 may have a pair of image capturing elements for acquiring respective image signals for left and right eyes that are compatible with 3D (Dimensional) display. The 3D display makes it possible for the surgeon 531 to grasp the depth of the body tissue more accurately at the surgical site. Incidentally, in case the image capturing section 702 is of the multi-panel type, a plurality of lens units 701 may also be provided in combination with the respective image capturing elements. The image capturing section 702 includes the solid-state image capturing device according to either one of the first through fourteenth embodiments, for example.

Furthermore, the image capturing section 702 may not necessarily be provided in the camera head 502. For example, the image capturing section 702 may be provided immediately behind the objective lens in the lens barrel 501.

The driving section 703 includes an actuator for moving the zoom lens and the focusing lens of the lens unit 701 by a predetermined distance along the optical axis under the control of the camera head controlling section 705. The lens unit 701 thus driven can appropriately adjust the magnification and focus of an image captured by the image capturing section 702.

The communicating section 704 includes a communication device for sending and receiving various pieces of information to and from the CCU 601. The communicating section 704 sends image signals obtained from the image capturing section 702 as RAW data via the transmission cable 700 to the CCU 601.

Moreover, the communicating section 704 receives control signals for controlling energization of the camera head 502 and supplies the received control signals to the camera head controlling section 705. The control signals include information relative to image capturing conditions, e.g., information indicating a frame rate for a captured image, information indicating an exposure value at the time an image is captured, and/or information indicating a magnification and focus for a captured image.

Note that the image capturing conditions including the frame rate, the exposure value, the magnification, and the focus may be designated by the user or may automatically set by the controlling section 713 of the CCU 601 on the basis of acquired image signals. In the latter case, what are generally called an AE (Auto Exposure) function, an AF (Auto Focus) function, and an AWB (Auto White Balance) function are incorporated in the endoscope 500.

The camera head controlling section 705 controls energization of the camera head 502 on the basis of control signals received from the CCU 601 via the communicating section 704.

The communicating section 711 includes a communication device for sending and receiving various pieces of information to and from the camera head 502. The communicating section 711 receives image signals sent from the camera head 502 via the transmission cable 700.

Moreover, the communicating section 711 sends control signals for controlling energization of the camera head 502 to the camera head 502. Image signals and control signals may be sent by way of electric communication or optical communication, for example.

The image processing section 712 performs various image processing processes on image signals sent as RAW data from the camera head 502.

The controlling section 713 performs various control processes relative to the capturing of images of a surgical site and the like by the endoscope 500 and the displaying of captured images of the surgical site and the like. For example, the controlling section 713 generates control signals for controlling energization of the camera head 502.

Moreover, the controlling section 713 controls the display device 602 to display captured images of a surgical site on the basis of image signals on which image processing processes have been performed by the image processing section 712. At this time, the controlling section 713 may recognize various objects in the captured images using various image recognition technologies. For example, the controlling section 713 can recognize surgical tools such as forceps, particular biological parts, bleeding, and mists given off when the energy treatment tool 512 is in use by detecting the shape and color of the edges of the objects in the captured images, and the like. When the controlling section 713 controls the display device 602 to display a captured image, the controlling section 713 may also display various pieces of surgery assistance information in overlapping relation to the image of the surgical site using the recognized results. When the displayed pieces of surgery assistance information are presented to the surgeon 531, they can reduce the burden on the surgeon 531 and allow the surgeon 531 to perform the surgery reliably.

The transmission cable 700 that interconnects the camera head 502 and the CCU 601 includes an electric signal cable compatible with electric signal communication or optical fibers compatible with optical communication, or a compound cable including an electric signal cable and optical fibers.

Herein, according to the illustrated example, wired communication is performed using the transmission cable 700. However, communication between the camera head 502 and the CCU 601 may be performed wirelessly.

While the embodiments of the present disclosure have been descried above, various changes and modifications may be made in the embodiments without departing the scope of the present disclosure. For example, a combination of two or more of the embodiments may be used to practice.

Note that the present disclosure may also have the following configurations.

(1)

A solid-state image capturing device including:
a first substrate;
a floating diffuser disposed in the first substrate;
a first transistor disposed on the first substrate;
a first insulating film disposed on the first substrate and the first transistor;
a first interconnect disposed in the first insulating film and electrically connected to the floating diffuser and the first transistor;
a second substrate disposed on the first insulating film;
a second transistor disposed on the second substrate; and
a second insulating film disposed on the second substrate and the second transistor.
   (2)

The solid-state image capturing device according to (1), in which the first transistor includes an amplifying transistor for converting electric charges stored in the floating diffuser to a voltage signal.

(3)

The solid-state image capturing device according to (1), further including:
a third transistor disposed on the first substrate;
a second interconnect disposed in the first insulating film and electrically connected to the third transistor;
a third insulating film disposed between the first insulating film and the second insulating film in the second substrate and extending through the second substrate; and
one or more first plugs disposed in the third insulating film, in which
the one or more first plugs include a first plug disposed on the second interconnect and are not disposed on the first interconnect.
   (4)

The solid-state image capturing device according to (3), in which the third transistor includes a transfer transistor for transferring electric charges generated by a photoelectric transducer disposed in the first substrate.

(5)

The solid-state image capturing device according to (3), further including:
a fourth transistor disposed on the first substrate; and
a third interconnect disposed in the first insulating film and electrically connected to the fourth transistor, in which
the one or more first plugs are not disposed on the third interconnect.
   (6)

The solid-state image capturing device according to (5), in which the fourth transistor includes a resetting transistor for resetting a potential of the floating diffuser.

(7)

The solid-state image capturing device according to (1), in which at least a portion of the first insulating film includes an insulating film having a dielectric constant lower than the dielectric constant of silicon oxide.

(8)

The solid-state image capturing device according to (1), further including:
a fourth insulating film disposed between the first insulating film and the second insulating film in the second substrate and extending through the second substrate, in which
the first interconnect is disposed in a position superposed on the fourth insulating film as viewed in plan.
   (9)

The solid-state image capturing device according to (8), in which at least a portion of the fourth insulating film includes an insulating film having a dielectric constant lower than the dielectric constant of silicon oxide.

(10)

The solid-state image capturing device according to (1), in which the first interconnect is disposed in a position superposed on a hollow region extending through the second substrate as viewed in plan.

(11)

The solid-state image capturing device according to (10), in which the first interconnect is held in contact with the hollow region.

(12)

The solid-state image capturing device according to (5), further including:
a fourth insulating film disposed between the first insulating film and the second insulating film in the second substrate and extending through the second substrate, in which
the third interconnect is disposed in a position superposed on the fourth insulating film as viewed in plan.
   (13)

The solid-state image capturing device according to (1), further including:
a fifth insulating film disposed between the first insulating film and the second insulating film in the second substrate and extending through the second substrate, in which
the first substrate includes a first portion annularly surrounded by the fifth insulating film.
   (14)

The solid-state image capturing device according to (13), in which the first interconnect is disposed in a position superposed on the first portion as viewed in plan.

(15)

The solid-state image capturing device according to (13), further including:
a second plug disposed on the first portion for controlling a potential of the first portion.
   (16)

The solid-state image capturing device according to (1), further including:
a resetting transistor for resetting a potential of the floating diffuser; and
a conversion-efficiency switching transistor disposed between the floating diffuser and the resetting transistor for switching between conversion efficiencies of a photoelectric transducer disposed in the first substrate.
   (17)

The solid-state image capturing device according to (16), in which the resetting transistor is disposed on the first substrate.

(18)

The solid-state image capturing device according to (16), in which the resetting transistor is disposed on the second substrate.

(19)

The solid-state image capturing device according to (1), further including:
a circuit disposed on the second substrate and including a transistor and a capacitor.
   (20)

The solid-state image capturing device according to (19), in which the circuit includes a sample and hold circuit.

### REFERENCE SIGNS LIST

1: Pixel
2: Pixel array area
3: Control circuit
4: Vertical drive circuit
5: Column signal processing circuit
6: Horizontal drive circuit
7: Output circuit
8: Vertical signal lines
9: Horizontal signal line
11: Substrate
11a: Well region
11b: Diffusion region
11c: Diffusion region
12: Element-separating insulating film
13 Pixel transistor
13a: Gate insulating film
13b: Gate electrode
13c: Side-wall insulating film
14: Pixel transistor
14a: Gate insulating film
14b: Gate electrode
14c: Side-wall insulating film
15: Interlayer insulating film
15′ : Interlayer insulating film
16: Contact plug
16a: Plug
16b: Plug
16c: Plug
16d: Plug
17: Interconnect layer
17a: Interconnect
17b: Interconnect
17c: Interconnect
18: Pixel transistor
18a: Gate insulating film
18b: Gate electrode
18c: Side-wall insulating film
21: Substrate
21a: Well region
21b: Diffusion region
21c: Diffusion region
21d: Diffusion region
21e: Diffusion region
21f: diffusion region
22: Insulating film
23: Element-separating insulating film
23′ : Element-separating insulating film
24: Pixel transistor
24a: Gate insulating film
24b: Gate electrode
24c: Side-wall insulating film
25: Pixel transistor
25a: Gate insulating film
25b: Gate electrode
25c: Side-wall insulating film
26: Interlayer insulating film
27: Contact plug
27a: Plug
27g: Plug
27c: Plug
27d: Plug
27e: Plug
27f: Plug
31: Through plug
31a: Plug
41: Hollow region
51: Substrate portion
52: Substrate portion
61: Sample and hold circuit
71: Substrate
72: Transistor
72a: Gate insulating film
72b: Gate electrode
72c: Side-wall insulating film
73: Interlayer insulating film
81: On-chip filter
82: On-chip lens

1. A solid-state image capturing device comprising:
a first substrate;
a floating diffuser disposed in the first substrate;
a first transistor disposed on the first substrate;
a first insulating film disposed on the first substrate and the first transistor;
a first interconnect disposed in the first insulating film and electrically connected to the floating diffuser and the first transistor;
a second substrate disposed on the first insulating film;
a second transistor disposed on the second substrate; and
a second insulating film disposed on the second substrate and the second transistor.

2. The solid-state image capturing device according to claim 1, wherein the first transistor includes an amplifying transistor for converting electric charges stored in the floating diffuser to a voltage signal.

3. The solid-state image capturing device according to claim 1, further comprising:
a third transistor disposed on the first substrate;
a second interconnect disposed in the first insulating film and electrically connected to the third transistor;
a third insulating film disposed between the first insulating film and the second insulating film in the second substrate and extending through the second substrate; and
one or more first plugs disposed in the third insulating film, wherein
the one or more first plugs include a first plug disposed on the second interconnect and are not disposed on the first interconnect.

4. The solid-state image capturing device according to claim 3, wherein the third transistor includes a transfer transistor for transferring electric charges generated by a photoelectric transducer disposed in the first substrate.

5. The solid-state image capturing device according to claim 3, further comprising:
a fourth transistor disposed on the first substrate; and
a third interconnect disposed in the first insulating film and electrically connected to the fourth transistor, wherein
the one or more first plugs are not disposed on the third interconnect.

6. The solid-state image capturing device according to claim 5, wherein the fourth transistor includes a resetting transistor for resetting a potential of the floating diffuser.

7. The solid-state image capturing device according to claim 1, wherein at least a portion of the first insulating film includes an insulating film having a dielectric constant lower than the dielectric constant of silicon oxide.

8. The solid-state image capturing device according to claim 1, further comprising:
a fourth insulating film disposed between the first insulating film and the second insulating film in the second substrate and extending through the second substrate, wherein
the first interconnect is disposed in a position superposed on the fourth insulating film as viewed in plan.

9. The solid-state image capturing device according to claim 8, wherein at least a portion of the fourth insulating film includes an insulating film having a dielectric constant lower than the dielectric constant of silicon oxide.

10. The solid-state image capturing device according to claim 1, wherein the first interconnect is disposed in a position superposed on a hollow region extending through the second substrate as viewed in plan.

11. The solid-state image capturing device according to claim 10, wherein the first interconnect is held in contact with the hollow region.

12. The solid-state image capturing device according to claim 5, further comprising:
a fourth insulating film disposed between the first insulating film and the second insulating film in the second substrate and extending through the second substrate, wherein
the third interconnect is disposed in a position superposed on the fourth insulating film as viewed in plan.

13. The solid-state image capturing device according to claim 1, further comprising:
a fifth insulating film disposed between the first insulating film and the second insulating film in the second substrate and extending through the second substrate, wherein
the first substrate includes a first portion annularly surrounded by the fifth insulating film.

14. The solid-state image capturing device according to claim 13, wherein the first interconnect is disposed in a position superposed on the first portion as viewed in plan.

15. The solid-state image capturing device according to claim 13, further comprising:
a second plug disposed on the first portion for controlling a potential of the first portion.

16. The solid-state image capturing device according to claim 1, further comprising:
a resetting transistor for resetting a potential of the floating diffuser; and
a conversion-efficiency switching transistor disposed between the floating diffuser and the resetting transistor for switching between conversion efficiencies of a photoelectric transducer disposed in the first substrate.

17. The solid-state image capturing device according to claim 16, wherein the resetting transistor is disposed on the first substrate.

18. The solid-state image capturing device according to claim 16, wherein the resetting transistor is disposed on the second substrate.

19. The solid-state image capturing device according to claim 1, further comprising:
a circuit disposed on the second substrate and including a transistor and a capacitor.

20. The solid-state image capturing device according to claim 19, wherein the circuit includes a sample and hold circuit.
